(19) United States
(12) Patent Application Publication
(10) Pub. No.: US 2026/0223662 A1
(43) Pub. Date: Jul. 30, 2026

(54) SEMICONDUCTOR DEVICES, METHODS OF OPERATING THEREOF, PACKAGE STRUCTURES, AND SYSTEMS

(71) Applicant: Yangtze Memory Technologies Holding Co., Ltd., Wuhan (CN)

(72) Inventors: Ke Liang, Wuhan (CN); Chunyuan Hou, Wuhan (CN); Zhiliang Xia, Wuhan (CN); Zongliang Huo, Wuhan (CN)

(21) Appl. No.: 19/240,251

(22) Filed: Jun. 17, 2025

(30) Foreign Application Priority Data
Jan. 26, 2025 (CN) 202510124081.4

(51) Int. Cl. H01L 23/528; H01L 23/00; H10B 80/00

(52) U.S. Cl. CPC H10W 20/43; H10B 80/00; H10W 90/792

(57) ABSTRACT

According to a first aspect of an implementation of the present disclosure, a semiconductor device is provided. The semiconductor device may include a first semiconductor structure and a second semiconductor structure. The first semiconductor structure may be bonded with a first side of the second semiconductor structure. The first semiconductor structure may include an analog-to-digital conversion circuit. The second semiconductor structure may include a memory array, a plurality of bit lines and a plurality of first connection structures. The memory array may be located between the plurality of bit lines and the first side of the second semiconductor structure. The plurality of first connection structures may be located between the plurality of bit lines and the first semiconductor structure. Each of the bit lines may be connected to the analog-to-digital conversion circuit through one of the first connection structures.

### CROSS-REFERENCE TO RELATED APPLICATIONS

This application claims the benefit of priority to Chinese Application No. 202510124081.4, filed on Jan. 26, 2025, which is hereby incorporated by reference in its entirety.

### TECHNICAL FIELD

Implementations of the present disclosure relate to the technical field of semiconductors, and relate to, but are not limited to, semiconductor devices, a methods of operating thereof, package structures, and systems.

### BACKGROUND

In the classical von Neumann computing architecture, a memory device is separate from a processor, and data is transmitted therebetween via a data bus. When executing a command, the processor first reads data from the memory device. After being processed, an updated data is written back into the memory device. Frequent data migration brings huge power consumption and time overhead. In addition, since a bandwidth of the memory device is limited, a processing speed of the processor is limited by an access speed of the memory device, which greatly affects the computing performance. With the rise of big data and artificial intelligence applications, a processing of massive data makes the bottleneck of von Neumann computing architecture more and more prominent.

### SUMMARY

According to a first aspect of an implementation of the present disclosure, a semiconductor device is provided. The semiconductor device may include a first semiconductor structure and a second semiconductor structure. The first semiconductor structure may be bonded with a first side of the second semiconductor structure. The first semiconductor structure may include an analog-to-digital conversion circuit. The second semiconductor structure may include a memory array, a plurality of bit lines and a plurality of first connection structures. The memory array may be located between the plurality of bit lines and the first side of the second semiconductor structure. The plurality of first connection structures may be located between the plurality of bit lines and the first semiconductor structure. Each of the bit lines may be connected to the analog-to-digital conversion circuit through one of the first connection structures.

In some implementations, the memory array may include a plurality of sub-memory planes arranged at intervals along an extending direction of the bit lines. In some implementations, at least one of the first connection structures may be located between two adjacent sub-memory planes.

In some implementations, the sub-memory plane may include a plurality of first memory blocks. In some implementations, at least one of the first connection structures may extend through at least one of the first memory blocks.

In some implementations, the second semiconductor structure may further include a second memory block located between two adjacent sub-memory planes. In some implementations, the first connection structure may be located between the two adjacent sub-memory planes extends through the second memory block.

In some implementations, the semiconductor device may include a third semiconductor structure bonded with a second side of the second semiconductor structure. In some implementations, the second side of the second semiconductor structure and the first side of the second semiconductor structure may be opposite to each other along an extension direction of the first connection structures. In some implementations, the third semiconductor structure may include a peripheral circuit. In some implementations, the second semiconductor structure further may include a plurality of second connection structures located between the plurality of bit lines and the third semiconductor structure. In some implementations, each of the bit lines may be connected to the peripheral circuit through one of the second connection structures.

In some implementations, the first semiconductor structure may further include a control circuit. In some implementations, the second semiconductor structure further may include a source layer located between the memory array and the first semiconductor structure. In some implementations, the source layer may be connected to at least one of the peripheral circuit and the control circuit.

In some implementations, the source layer may include a plurality of sub-source layers arranged at intervals along the extending direction of the bit lines. In some implementations, each of the sub-source layers may be correspondingly connected to one of the sub-memory planes. In some implementations, the second semiconductor structure may further include a third connection structure and a fourth connection structure. In some implementations, the third connection structure may be located between a first sub-source layer of the plurality of sub-source layers and the third semiconductor structure. In some implementations, the first sub-source layer may be connected to the peripheral circuit through the third connection structure. In some implementations, the fourth connection structure may be located between a second sub-source layer of the plurality of sub-source layers and the first semiconductor structure. In some implementations, the second sub-source layer may be connected to the control circuit through the fourth connection structure.

In some implementations, the sub-memory plane connected to the first sub-source layer may have a first side and a second side opposite to each other along an arrangement direction of the plurality of bit lines. In some implementations, the third connection structure may be located on the first side or the second side of the sub-memory plane connected to the first sub-source layer. In some implementations, the arrangement direction of the plurality of bit lines may intersect with an extension direction of the bit lines.

In some implementations, the second semiconductor structure may further include a plurality of conductive layers located between the source layer and the first semiconductor structure and arranged at intervals along the extending direction of the bit lines. In some implementations, the first sub-source layer may be connected to the third connection structure through one of the conductive layers. In some implementations, the second sub-source layer may be connected to the fourth connection structure through another conductive layer of the conductive layers.

In some implementations, the second semiconductor structure may further include at least one connection portion. In some implementations, the connection portion may be located between two adjacent conductive layers. In some implementations, two opposite ends of the connection portion along the extension direction of the bit lines may be respectively connected to the two adjacent conductive layers.

In some implementations, the first semiconductor structure may include a first bonding layer. In some implementations, the first bonding layer may be located between the second semiconductor structure and the analog-to-digital conversion circuit. In some implementations, the second semiconductor structure may include a second bonding layer and a third bonding layer, the second bonding layer may be located between the memory array and the first bonding layer, the third bonding layer may be located between the plurality of second connection structures and the third semiconductor structure, and the second bonding layer may be bonded to the first bonding layer. In some implementations, the third semiconductor structure may further include a fourth bonding layer between the peripheral circuit and the third bonding layer, and the fourth bonding layer may be bonded to the third bonding layer.

In some implementations, a first end of the first connection structure may be connected to the bit line, a second end of the first connection structure may be connected to the second bonding layer, and the first end of the first connection structure and a second end of the first connection structure may be opposite to each other along the extension direction of the first connection structures. In some implementations, a first end of the second connection structure may be connected to the bit line, a second end of the second connection structure may be connected to the third bonding layer, and the first end of the second connection structure and the second end of the second connection structure may be opposite to each other along an extending direction of the second connection structure.

In some implementations, a cross-sectional size of the first end of the first connection structure may be less than or equal to a cross-sectional size of the second end of the first connection structure. In some implementations, a cross-sectional size of the first end of the second connection structure may be less than or equal to a cross-sectional size of the second end of the second connection structure.

In some implementations, the semiconductor device may include a three-dimensional NAND memory.

According to another aspect of the present disclosure, a semiconductor device is provided. The semiconductor device may include a first semiconductor structure and a second semiconductor structure. The first semiconductor structure may be bonded with a first side of the second semiconductor structure. The first semiconductor structure may include an analog-to-digital conversion circuit. The second semiconductor structure may include a plurality of sub-memory planes, a plurality of bit lines and a plurality of first connection structures. The plurality of sub-memory planes may be located between the plurality of bit lines and the first side of the second semiconductor structure and arranged at intervals along an extending direction of the bit lines. At least one of the first connection structures may be located between two adjacent sub-memory planes and may be respectively connected to the bit line and the analog-to-digital conversion circuit.

In some implementations, the sub-memory plane may include a plurality of first memory blocks. In some implementations, at least one of the first connection structures may extend through at least one of the first memory blocks.

In some implementations, the second semiconductor structure may further include a second memory block located between two adjacent sub-memory planes. In some implementations, the first connection structure located between the two adjacent sub-memory planes may extend through the second memory block.

In some implementations, the semiconductor device may further include a third semiconductor structure, the third semiconductor structure may be bonded with a second side of the second semiconductor structure, and the second side of the second semiconductor structure and the first side of the second semiconductor structure may be opposite to each other along an extension direction of the first connection structures. In some implementations, the third semiconductor structure may include a peripheral circuit. In some implementations, the second semiconductor structure may further include a plurality of second connection structures located between the plurality of bit lines and the third semiconductor structure, and each of the bit lines may be connected to the peripheral circuit through one of the second connection structures.

In some implementations, the first semiconductor structure may further include a control circuit. In some implementations, the second semiconductor structure may further include a source layer located between the plurality of sub-memory planes and the first semiconductor structure. In some implementations, the source layer may be connected to at least one of the peripheral circuit and the control circuit.

In some implementations, the source layer may include a plurality of sub-source layers arranged at intervals along the extending direction of the bit lines. In some implementations, each of the sub-source layers may be correspondingly connected to one of the sub-memory planes. In some implementations, the second semiconductor structure may further include a third connection structure and a fourth connection structure. In some implementations, the third connection structure may be located between a first sub-source layer of the plurality of sub-source layers and the third semiconductor structure. In some implementations, the first sub-source layer may be connected to the peripheral circuit through the third connection structure. In some implementations, the fourth connection structure may be located between a second sub-source layer of the plurality of sub-source layers and the first semiconductor structure. In some implementations, the second sub-source layer may be connected to the control circuit through the fourth connection structure.

In some implementations, the sub-memory plane connected to the first sub-source layer may have a first side and a second side opposite to each other along an arrangement direction of the plurality of bit lines. In some implementations, the third connection structure may be located on the first side or the second side of the sub-memory plane connected to the first sub-source layer. In some implementations, the arrangement direction of the plurality of bit lines may intersect with the extension direction of the bit lines.

In some implementations, the second semiconductor structure may further include a plurality of conductive layers located between the source layer and the first semiconductor structure and arranged at intervals along the extending direction of the bit lines. In some implementations, the first sub-source layer may be connected to the third connection structure through one of the conductive layers. In some implementations, the second sub-source layer may be connected to the fourth connection structure through another conductive layer of the conductive layers.

In some implementations, the second semiconductor structure may further include at least one connection portion located between two adjacent conductive layers. In some implementations, two opposite ends of the connection portion along the extension direction of the bit lines may be respectively connected to the two adjacent conductive layers.

In some implementations, the first semiconductor structure may include a first bonding layer located between the second semiconductor structure and the analog-to-digital conversion circuit. In some implementations, the second semiconductor structure may include a second bonding layer and a third bonding layer. In some implementations, the second bonding layer may be located between the plurality of sub-memory planes and the first bonding layer. In some implementations, the third bonding layer may be located between the plurality of second connection structures and the third semiconductor structure. In some implementations, the second bonding layer may be bonded to the first bonding layer. In some implementations, the third semiconductor structure may further include a fourth bonding layer between the peripheral circuit and the third bonding layer. In some implementations, the fourth bonding layer may be bonded to the third bonding layer.

In some implementations, a first end of the first connection structure may be connected to the bit line, a second end of the first connection structure is connected to the second bonding layer. In some implementations, the first end of the first connection structure and the second end of the first connection structure may be opposite to each other along an extension direction of the first connection structures. In some implementations, a first end of the second connection structure may be connected to the bit line, a second end of the second connection structure is connected to the third bonding layer. In some implementations, the first end of the second connection structure and the second end of the second connection structure may be opposite to each other along an extending direction of the second connection structures.

In some implementations, a cross-sectional size of the first end of the first connection structure may be less than or equal to a cross-sectional size of the second end of the first connection structure. In some implementations, a cross-sectional size of the first end of the second connection structure may be less than or equal to a cross-sectional size of the second end of the second connection structure.

In some implementations, any one of the plurality of first connection structures may be located between two adjacent sub-memory planes.

In some implementations, a portion of the plurality of first connection structures may be located between two adjacent sub-memory planes. In some implementations, another portion of plurality of first connection structures may be located on two opposite sides of the plurality of sub-memory planes along the extending direction of the bit lines.

In some implementations, the semiconductor device may include a three-dimensional NAND memory.

According to a further aspect of the present disclosure, a method of operating a semiconductor device is provided. The method may include performing a first operation on a plurality of sub-memory planes in a second semiconductor structure to obtain analog computing information. The method may include transmitting the analog computing information to an analog-to-digital conversion circuit in a first semiconductor structure through a plurality of bit lines and a plurality of first connection structures in the second semiconductor structure. The first semiconductor structure may be bonded with a first side of the second semiconductor structure. At least one of the first connection structures may be located between two adjacent sub-memory planes and respectively connected to the bit line and the analog-to-digital conversion circuit. The method may include converting the analog computing information into digital information through the analog-to-digital conversion circuit.

In some implementations, the method may include performing a second operation on the digital information through a data processing circuit in the first semiconductor structure. In some implementations, the data processing circuit may be connected to the analog-to-digital conversion circuit.

In some implementations, the first operation may include a multiply-accumulate operation. In some implementations, the second operation may include one or more of a compensation, an activation, a shift or a pooling operation.

According to still another aspect of the present disclosure, a package structure is provided. The package structure may include a package substrate. The package structure may include a semiconductor device including a first semiconductor structure and a second semiconductor structure. The first semiconductor structure may be bonded with a first side of the second semiconductor structure. The first semiconductor structure may include an analog-to-digital conversion circuit. The second semiconductor structure may include a memory array, a plurality of bit lines and a plurality of first connection structures, the memory array may be located between the plurality of bit lines and the first side of the second semiconductor structure, the plurality of first connection structures may be located between the plurality of bit lines and the first semiconductor structure, and each of the bit lines may be connected to the analog-to-digital conversion circuit through one of the first connection structures. The package structure may include an encapsulation layer. The semiconductor device may be located on a side of the package substrate, and the encapsulation layer may encapsulate the semiconductor device.

According to still a further aspect of the present disclosure, a package structure is provided. The package structure may include a package substrate. The package structure may include a semiconductor device including a first semiconductor structure and a second semiconductor structure. The first semiconductor structure may be bonded with a first side of the second semiconductor structure. The first semiconductor structure may include an analog-to-digital conversion circuit. The second semiconductor structure may include a plurality of sub-memory planes, a plurality of bit lines and a plurality of first connection structures, the plurality of sub-memory planes may be located between the plurality of bit lines and the first side of the second semiconductor structure and arranged at intervals along an extending direction of the bit lines, and at least one of the first connection structures may be located between two adjacent sub-memory planes and is respectively connected to the bit line and the analog-to-digital conversion circuit. The package structure may include an encapsulation layer. The semiconductor device may be located on a side of the package substrate, and the encapsulation layer may encapsulate the semiconductor device.

According to yet another aspect of the present disclosure, a system is provided. The system may include at least one semiconductor device. The at least one semiconductor device may include a first semiconductor structure and a second semiconductor structure. The first semiconductor structure may be bonded with a first side of the second semiconductor structure. The first semiconductor structure may include an analog-to-digital conversion circuit. The second semiconductor structure may include a memory array, a plurality of bit lines and a plurality of first connection structures, the memory array may be located between the plurality of bit lines and the first side of the second semiconductor structure, the plurality of first connection structures may be located between the plurality of bit lines and the first semiconductor structure, and each of the bit lines may be connected to the analog-to-digital conversion circuit through one of the first connection structures. The system may include a controller coupled to the semiconductor device. The controller may be configured to send data to and receive data from the semiconductor device.

According to yet a further aspect of the present disclosure, a system is provided. The system may include at least one semiconductor device. The at least one semiconductor device may include a first semiconductor structure and a second semiconductor structure. The first semiconductor structure may be bonded with a first side of the second semiconductor structure. The first semiconductor structure may include an analog-to-digital conversion circuit. The second semiconductor structure may include a plurality of sub-memory planes, a plurality of bit lines and a plurality of first connection structures. The plurality of sub-memory planes may be located between the plurality of bit lines and the first side of the second semiconductor structure and arranged at intervals along an extending direction of the bit lines. At least one of the first connection structures may be located between two adjacent sub-memory planes and may be respectively connected to the bit line and the analog-to-digital conversion circuit. The system may include a controller coupled to the semiconductor device. The controller may be configured to send data to and receive data from the semiconductor device.

In the implementations of the present disclosure, by bonding the first semiconductor structure with a first side of the second semiconductor structure, the first semiconductor structure includes an analog-to-digital conversion circuit; the second semiconductor structure includes a memory array, a plurality of bit lines and a plurality of first connection structures, the memory array is located between the plurality of bit lines and the first side of the second semiconductor structure, the plurality of first connection structures are located between the plurality of bit lines and the first semiconductor structure, and each bit line is connected to the analog-to-digital conversion circuit through one of the first connection structures. In the first aspect, the three-dimensional integration of the semiconductor device can be realized, the chip size is reduced, and the storage density is improved; in the second aspect, the analog computing information sensed on each bit line may be transmitted to the analog-to-digital conversion circuit through the first connection structure connected with the bit line, which is beneficial to improving the parallelism of the in-memory computation.

### BRIEF DESCRIPTION OF DRAWINGS

In the drawings, like reference numbers refer to like or similar parts or elements throughout the several figures unless otherwise specified. These figures are not necessarily drawn to scale. It should be understood that these figures depict only some implementations disclosed in accordance with the present application and should not be construed as limiting the scope of the present application.

FIG. 1 is a schematic diagram of a semiconductor device according to an implementation of the present disclosure.

FIG. 2 is a schematic diagram of a memory plane according to an implementation of the present disclosure.

FIG. 3 is a schematic diagram of a semiconductor device including a memory array and a peripheral circuit according to an implementation of the present disclosure.

FIG. 4 is a cross-sectional diagram of a memory array including a memory string according to an implementation of the present disclosure.

FIG. 5 is a schematic diagram of a semiconductor device including a peripheral circuit and a memory array according to an implementation of the present disclosure.

FIG. 6 is a schematic diagram where an input voltage is input to a memory array from a top select line according to an implementation of the present disclosure.

FIG. 7 is a schematic diagram of a plurality of memory strings coupled to a bit line according to an implementation of the present disclosure.

FIG. 8 is a structural diagram of a semiconductor device according to an implementation of the present disclosure.

FIG. 9 is a structural diagram of another semiconductor device according to an implementation of the present disclosure.

FIG. 10 is a structural diagram of still another semiconductor device according to an implementation of the present disclosure.

FIG. 11 is a top view of channel structures, dummy channel structures and first connection structures according to an implementation of the present disclosure.

FIGS. 12A-12D are schematic diagrams of arrangements of first connection structures according to implementations of the present disclosure.

FIG. 13 is a structural diagram of a semiconductor device according to an implementation of the present disclosure.

FIG. 14 is a flow diagram of a method of operating a semiconductor device according to an implementation of the present disclosure.

FIG. 15A is a schematic diagram of a system according to an implementation of the present disclosure.

FIG. 15B is a schematic diagram of another system according to an implementation of the present disclosure.

FIG. 16A is a schematic diagram of an exemplary memory card with a memory system according to an implementation of the present disclosure.

FIG. 16B is a schematic diagram of an exemplary solid state disk with a memory system according to an implementation of the present disclosure.

### DETAILED DESCRIPTION

For ease of understanding of the present disclosure, exemplary implementations of the present disclosure will be described in more detail below with reference to the accompanying drawings. While exemplary implementations of the present disclosure are shown in the drawings, it should be understood that the present disclosure may be implemented in various forms and should not be limited by the specific implementations set forth herein. Rather, these implementations are provided to enable a more thorough understanding of the present disclosure and to fully convey the scope of the present disclosure to those skilled in the art.

In the following description, numerous specific details are given in order to provide a more thorough understanding of the present disclosure. It will be apparent to those skilled in the art, however, that the present disclosure may be practiced without one or more of these details. In some implementations, to avoid confusion with the present disclosure, some technical features known in the art are not described; that is, all features of the actual implementations may not be described herein, and well-known functions and structures are not described in detail.

In general, the terms may be understood at least in part from the use in the context. For implementation, depending at least in part on context, the term “one or more” as used herein may be used to describe any feature, structure, or characteristic in a singular sense, or may be used to describe a combination of features, structures, or characteristics in a plural sense. Similarly, terms such as “a”, “an” or “the” may likewise be understood to convey singular usage or convey plural usage, depending at least in part on context. In addition, the term “based on” may be understood to not necessarily be intended to convey an exclusive set of factors, and may, instead, allow for existence of additional factors not necessarily explicitly described, again, depending at least in part on context.

Unless otherwise defined, the terminology used herein is for the purpose of describing particular implementations only and is not limiting of the present disclosure. As used herein, the singular forms “a,” “an,” and “the” are intended to include plural forms as well, unless the context clearly indicates otherwise. It should also be understood that the terms “consisted of” and/or “including”, when used in this specification, determine the presence of stated features, integers, steps, operations, elements, and/or components, but do not preclude the presence or addition of one or more other features, integers, steps, operations, elements, components, and/or groups. As used herein, the term “and/or” includes any and all combinations of related listed items.

For a thorough understanding of the present disclosure, detailed steps and detailed structures will be presented in the following description in order to explain the technical solutions of the present disclosure. Implementations of the present disclosure are described in detail below, however, other implementations may be provided in addition to the detailed description.

In the classical von Neumann computing architecture, a memory device is separate from a processor, and data is transmitted therebetween via the data bus. When executing the command, the processor first reads the data from the memory device, and then writes an updated data back into the memory device, and the frequent data migration brings huge power consumption and time overheads; in addition, since a bandwidth of the memory device is limited, a processing speed of the processor is limited by an access speed of the memory device, which greatly affects the computing performance. With the rise of big data and artificial intelligence applications, the processing of massive data makes the bottleneck of von Neumann computing architecture more and more prominent. In order to solve the bottleneck of the classic von Neumann computing architecture, a computing in memory chip architecture emerges, and the basic idea thereof is to embed a computing function in the memory device, and directly use the memory device to perform logical computing, thereby reducing the amount of data transmission and the transmission distance between the memory device and the processor, reducing the power consumption, and improving the computing performance, thereby being expected to construct a high computing ability, high bandwidth and energy efficient computing system.

The computing in memory chip has both storage and computing ability depending on its own physical characteristics. The storage capability refers to the ability of different memory devices to achieve a stored value by changing the conductance value thereof according to their physical characteristics, and the computing ability refers to the ability to complete the vector matrix multiplication computation within a certain time by constructing an array composed of memory devices, according to Ohm's law and Kirchhoff's law. The computing in memory chip includes, but is not limited to, Static Random Access Memory (SRAM), NAND flash memory, and Dynamic Random Access Memory (DRAM). The NAND flash memory is a non-volatile memory and has a large capacity, thus becoming a widely concerned object in computing in memory chips. The contents of the NAND flash memory will be correspondingly introduced below.

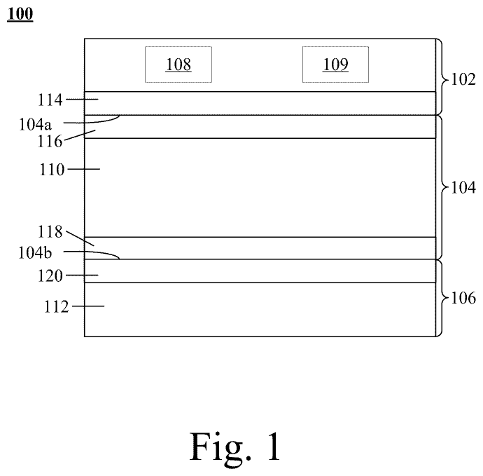

FIG. 1 is a schematic diagram of a semiconductor device according to an implementation of the present disclosure, and the semiconductor device includes, but is not limited to, 3D NAND. Referring to FIG. 1, the semiconductor device 100 includes a first semiconductor structure 102 and a second semiconductor structure 104, and the first semiconductor structure 102 is bonded with a first side 104a of the second semiconductor structure 104. The first semiconductor structure 102 and the second semiconductor structure 104 may be in different planes, the first semiconductor structure 102 and the second semiconductor structure 104 are stacked on each other; that is, the first semiconductor structure 102 and the second semiconductor structure 104 are at different levels, so that the planar size of the semiconductor device 100 can be reduced. In some implementations, the first semiconductor structure 102 and the second semiconductor structure 104 may be formed on different substrates, respectively. For example, the first semiconductor structure 102 is formed on a first substrate and the second semiconductor structure 104 is formed on a second substrate, and then the first semiconductor structure 102 and the second semiconductor structure 104 are stacked on each other using various bonding techniques such as hybrid bonding, transfer bonding, or the like.

The first semiconductor structure 102 includes an analog-to-digital conversion circuit 108 configured to convert an analog signal into a digital signal and transmit the digital signal to a data processing circuit 109. As an example, the analog-to-digital conversion circuit 108 is configured to convert an analog computing information obtained by performing a first operation on the memory array 110 in the second semiconductor structure 104 into a digital information, and transmit the digital information to the data processing circuit 109; the data processing circuit 109 is configured to perform a second operation on the digital information. The first operation includes a multiply-accumulate operation, and the second operation includes one or more of a compensation, an activation, a shift, or a pooling operation.

It should be noted that, in the implementation shown in FIG. 1, the analog-to-digital conversion circuit 108 and the data processing circuit 109 are both located in the first semiconductor structure 102; that is, the first semiconductor structure 102 includes the analog-to-digital conversion circuit 108 and the data processing circuit 109. However, in other examples, the data processing circuit 109 may be located in other semiconductor structures; for example, a data processing circuit is formed on another substrate, and is bonded with a first substrate on which the analog-to-digital conversion circuit 108 is formed, thereby realizing the connection between the analog-to-digital conversion circuit 108 and the data processing circuit 109.

The analog-to-digital conversion circuit 108 includes, but is not limited to, an analog-to-digital converter (ADC). The data processing circuit 109 includes a processor, the processor may include a dedicated processor, and the dedicated processor includes, but is not limited to, a central processing unit (CPU), a graphics processing unit (GPU), a digital signal processor (DSP), a tensor processing unit (TPU), a video processing unit (VPU), a neural processing unit (NPU), a secure processing unit (SPU), a physical processing unit (PPU), and an image signal processor (ISP). In an implementation, the data processing circuit includes an NPU. The NPU may perform operations such as arithmetic/logical operation, rotation and shift operation, compensation operation, activation operation and pooling operation, and the like. In some implementations, the activation operation may be implemented by activation functions stored in the NPU, which may include, but is not limited to, a step function, a correction function, a sigmoid function, a hyperbolic tangent (tanh) function, and a softplus function (also referred to as smooth correction).

The second semiconductor structure 104 includes a memory array 110, which may perform a first operation to obtain an analog computing information; and the analog computing information may be transmitted to the analog-to-digital conversion circuit 108.

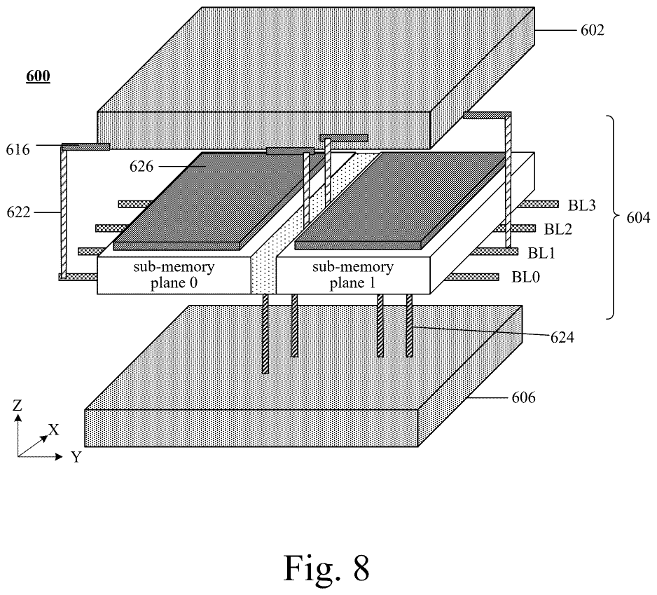

The second semiconductor structure 104 may further include a plurality of bit lines and a plurality of first connection structures. For example, bit lines BL0 to BL3 and a plurality of first connection structures 622 are shown in FIGS. 8 to 10. The memory array 110 is located between the plurality of bit lines and a first side 104a of the second semiconductor structure 104, and the plurality of first connection structures are located between the plurality of bit lines and the first semiconductor structure 102. It may be understood that the plurality of bit lines are located on a side of the memory array 110 facing away from the first semiconductor structure 102, each bit line is connected to the analog-to-digital conversion circuit 108 through one of the first connection structures, and the analog computing information obtained by performing the first operation on the memory array 110 may be transmitted to the analog-to-digital conversion circuit 108 through respective bit line and first connection structure.

In an implementation of the present disclosure, by bonding the first semiconductor structure 102 with the first side 104a of the second semiconductor structure 104, the first semiconductor structure 102 includes an analog-to-digital conversion circuit 108, the second semiconductor structure 104 includes a memory array 110, a plurality of bit lines and a plurality of first connection structures, the memory array 110 is located between the plurality of bit lines and the first side 104a of the second semiconductor structure 104, the plurality of first connection structures are located between the plurality of bit lines and the first semiconductor structure 102, and each bit line is connected to the analog-to-digital conversion circuit 108 through a first connection structure. In the first aspect, the three-dimensional integration of the semiconductor device 100 can be realized, the chip size is reduced, and the storage density is improved; in the second aspect, the analog computing information sensed on each bit line may be transmitted to the analog-to-digital conversion circuit 108 through the first connection structure connected with the bit line, which is beneficial to improving the parallelism of the in-memory computation.

In some implementations, referring to FIG. 1, the semiconductor device 100 further includes a third semiconductor structure 106, the third semiconductor structure 106 is bonded with a second side 104b of the second semiconductor structure 104, and the second side 104b of the second semiconductor structure 104 and the first side 104a of the second semiconductor structure 104 are opposite to each other along an extension direction of the first connection structures. As an example, referring to FIG. 1, the third semiconductor structure 106, the second semiconductor structure 104, and the first semiconductor structure 102 are sequentially stacked along the extension direction of the first connection structures; that is, the third semiconductor structure 106 and the first semiconductor structure 102 are respectively integrated on two opposite sides of the second semiconductor structure 104 along the extension direction of the first connection structures, so that the planar size of the semiconductor device 100 can be reduced, the integration level can be improved, and the storage density can be increased. In some implementations, the third semiconductor structure 106 may be formed on a third substrate, stacked with first semiconductor structure 102 and the second semiconductor structure 104 each other by using various bonding techniques such as hybrid bonding, transfer bonding, or the like.

The third semiconductor structure 106 includes a peripheral circuit 112; the second semiconductor structure 104 further includes a plurality of second connection structures; for example, FIGS. 8-10 show a plurality of second connection structures 624. The plurality of second connection structures are located between the plurality of bit lines and the third semiconductor structure 106. It may be understood that the plurality of bit lines are located between the memory array 110 and the third semiconductor structure 106, and each bit line is connected to the peripheral circuit 112 through a second connection structure. A read result obtained by the memory array 110 performing the read operation, a program verification result obtained by performing a program verification operation, and an erase verification result obtained by performing an erase verification operation may be transmitted to the peripheral circuit 112 through respective bit line and second connection structure.

In some implementations, the first semiconductor structure 102 and the second semiconductor structure 104 may be vertically connected by bonding. As an example, referring to FIG. 1, the first semiconductor structure 102 includes a first bonding layer 114, the second semiconductor structure 104 includes a second bonding layer 116, and the second bonding layer 116 is bonded to the first bonding layer 114, so that the first semiconductor structure 102 and the second semiconductor structure 104 are vertically connected. In the bonded first semiconductor structure 102 and second semiconductor structure 104, the first bonding layer 114 is located between the second semiconductor structure 104 and the analog-to-digital conversion circuit 108, and the second bonding layer 116 is located between the memory array 110 and the first bonding layer 114.

In some implementations, the second semiconductor structure 104 and the third semiconductor structure 106 may be vertically connected by bonding. As an example, referring to FIG. 1, the second semiconductor structure 104 includes a third bonding layer 118, and the third semiconductor structure 106 includes a fourth bonding layer 120, and the fourth bonding layer 120 is bonded to the third bonding layer 118, so that the second semiconductor structure 104 and the third semiconductor structure 106 are vertically connected. In the bonded second semiconductor structure 104 and third semiconductor structure 106, the third bonding layer 118 is located between the plurality of second connection structures and the third semiconductor structure 106, and the fourth bonding layer 120 is located between the peripheral circuit 112 and the third bonding layer 118.

It should be noted that the bonding described above includes a hybrid bonding (also referred to as a “metal/dielectric hybrid bonding”), which is a direct bonding technique, e.g., forming a bond between the surfaces without using an intermediate layer such as a solder or an adhesive, and may simultaneously obtain a metal-metal bonding and a dielectric-to-dielectric bonding. It should be noted that the “bonding” mentioned in the present disclosure may include any suitable bonding technique, such as the hybrid bonding mentioned above, anodic bonding, fusion bonding, transfer bonding, adhesive bonding, and eutectic bonding, or the like.

In some implementations, the semiconductor device 100 further includes a first bonding interface between the first bonding layer 114 and the second bonding layer 116, and a second bonding interface between the third bonding layer 118 and the fourth bonding layer 120. Data transfer between the first semiconductor structure 102 and the second semiconductor structure 104 may be achieved by interconnects (e.g., bonding contacts) across the first bonding interface. Data transfer between the second semiconductor structure 104 and the third semiconductor structure 106 may be achieved by interconnects (e.g., bonding contacts) across the second bonding interface.

In some implementations, the first bonding layer 114 includes first bonding contacts and a first dielectric layer that isolates the first bonding contacts, the second bonding layer 116 includes second bonding contacts and a second dielectric layer that isolates the second bonding contacts, where the first bonding contact is bonded to the second bonding contact, and the first dielectric layer is bonded to the second dielectric layer.

In some implementations, the third bonding layer 118 includes third bonding contacts and a third dielectric layer that isolates the third bonding contacts; the fourth bonding layer 120 includes fourth bonding contacts and a fourth dielectric layer that isolates the fourth bonding contacts; the third bonding contact is bonded to the fourth bonding contact, and the third dielectric layer is bonded to the fourth dielectric layer.

In some implementations, the bonding contact may include a conductive material including, but not limited to, one or more of tungsten, cobalt, copper, aluminum, or polysilicon. As an example, the bonding contact of the bonding layer includes copper, the remaining region of the bonding layer may be formed of a dielectric including, but not limited to, one or more of silicon oxide, silicon nitride, silicon oxynitride, or a low-k dielectric. The bonding contact and the surrounding dielectric in the bonding layer may be used for hybrid bonding, and a metal-to-metal bonding and a dielectric-to-dielectric bonding may be obtained simultaneously.

It should be noted that an analog computing information obtained by the memory array 110 performing a first operation may be transmitted to the analog-to-digital conversion circuit 108 through the respective bit line, the first connection structure, the second bonding layer 116 and the first bonding layer 114. Each of the read result obtained by the memory array 110 performing the read operation, the program verify result obtained by performing the program verify operation, and the erase verify result obtained by performing the erase verify operation may be transmitted to the peripheral circuit 112 through the corresponding bit line, the second connection structure, the third bonding layer 118 and the fourth bonding layer 120.

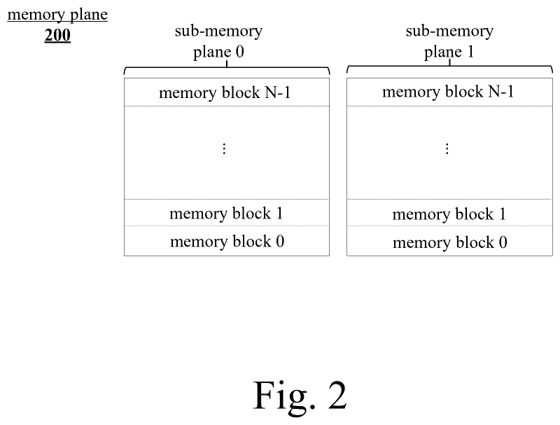

FIG. 2 is a schematic diagram of a memory plane according to an implementation of the present disclosure. The memory array may include a plurality of memory planes 200 (Plane), for example, the memory array includes 2, 4, 8, or other number of memory planes. Each memory plane 200 may include a plurality of sub-memory planes, for example, a sub-memory plane 0 and a sub-memory plane 1 are shown in FIG. 2. Each sub-memory plane may include a plurality of memory blocks, for example, a memory block 0 to a memory block (N−1) are shown in FIG. 2, where N is an integer greater than 1. It should be noted that the number of the sub-memory planes in the memory plane 200 and the number of the memory blocks in the sub-memory plane are not limited to those shown in FIG. 2, and may also be other number. In practical applications, the number of memory planes 200, the number of sub-memory planes, and the number of memory blocks in the memory array may be reasonably configured according to usage requirements.

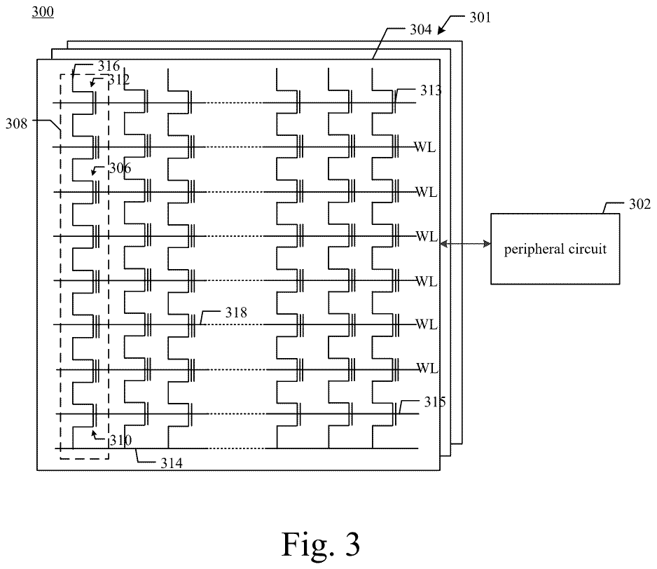

FIG. 3 is a schematic diagram of a semiconductor device including an memory array and a peripheral circuit according to an implementation of the present disclosure, and for ease of understanding, an implementation in which the memory array 301 is a three-dimensional NAND type memory array is described as an example, where the memory cell 306 is a NAND memory cell, memory cells 306 are provided in an array of memory strings 308, and each memory string 308 extends vertically. In some implementations, each memory string 308 includes a plurality of memory cells 306 coupled in series and stacked vertically. Each memory cell 306 may hold a continuous, analog value, e.g., voltage or charge that depends on the number of electrons trapped within a region of the memory cell 306. Each memory cell 306 may be either a floating gate type memory cell including a floating gate transistor or a charge trapping type memory cell including a charge trapping transistor.

In some implementations, each memory cell 306 is a Single Level Cell (SLC) having two possible memory states and thus may store one bit of data. For example, the first memory state “0” may correspond to a first voltage range and the second memory state “1” may correspond to a second voltage range. In other implementations, each memory cell 306 is a multi-level cell that is capable of storing more than a single bit of data in four or more than four memory states, e.g., a multi-level cell (MLC) storing two bits per cell, a triple level cell (TLC) storing three bits per cell, or a Quad-Level Cell (QLC) storing four bits per cell.

Referring to FIG. 3, each memory string 308 may include a bottom select transistor (BSG) 310 at its source terminal and a top select transistor (TSG) 312 at its drain terminal. The bottom select transistor 310 and the top select transistor 312 may be configured to activate selected memory strings 308 during read and program operations. In some implementations, the source terminals of the memory strings 308 in the same memory block 304 may be coupled through a common source line (CSL) 314. In other words, all memory strings 308 in the same memory block 304 have an array common source (“ACS”). According to some implementations, the top select transistor 312 of each memory string 308 is coupled to a respective bit line 316 from which data may be read or written via an output bus (not shown). In some implementations, each memory string 308 is configured to be selected or deselected by applying a select voltage (e.g., a voltage higher than a threshold voltage of the top select transistor 312) or a deselect voltage (e.g., 0V) to respective top select transistor 312 through one or more top select lines (TSL) 313 and/or by applying a select voltage (e.g., a voltage above a threshold voltage of the bottom select transistor 310) or a deselect voltage (e.g., 0V) to respective bottom select transistor 310 through one or more bottom select lines (BSL) 315.

Referring to FIG. 3, memory strings 308 may be organized into a plurality of memory blocks 304, each of which may have a common source line 314. In some implementations, each memory block 304 is the basic data unit for erase operations, e.g., all memory cells 306 on the same memory block 304 are erased at the same time. To erase memory cells 306 in a selected memory block, common source lines 314 coupled to the selected memory block as well as unselected memory blocks in the same plane as selected memory block may be biased with an erase voltage. It should be understood that in some implementations, the erase operation may be performed at a half memory block level, a quarter memory block level, or a level having any suitable number of memory blocks or any suitable fractions of a memory block. Memory cells 306 of adjacent memory strings 308 may be coupled through word lines 318 that select which row of memory cells 306 is affected by read and program operations.

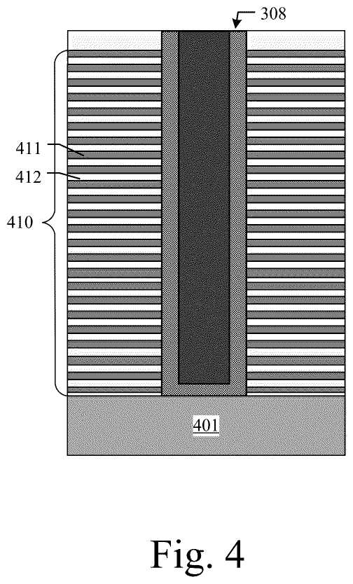

FIG. 4 is a cross-sectional diagram of a memory array including a memory string according to an implementation of the present disclosure. Referring to FIG. 4, the stacked structure 410 includes a plurality of gate layers 411 and a plurality of insulating layers 412 alternately stacked, and a memory string 308 extending through the gate layers 411 and the insulating layers 412. The gate layers 411 and the insulating layers 412 may be alternately stacked, and two adjacent gate layers 411 are separated by an insulating layer 412. The number of memory cells included in the memory array is mainly related to the number of pairs of gate layers 411 and insulating layers 412 in the stacked structure 410.

The composition material of the gate layer 411 may include a conductive material. The conductive material includes, but is not limited to, tungsten, cobalt, copper, aluminum, polysilicon, doped silicon, silicide, or any combination thereof. In some implementations, each gate layer 411 includes a metal layer such as a tungsten layer. In some implementations, each gate layer 411 includes a doped polysilicon layer. Each gate layer 411 may include a control gate surrounding the memory cell. The gate layer 411 at the top of the stacked structure 410 may extend laterally as a top select line, the gate layer 411 at the bottom of the stacked structure 410 may extend laterally as a bottom select line, and the gate layers 411 extending laterally between the top select line and the bottom select line may act as word line layers.

In some implementations, the stacked structure 410 may be disposed on the semiconductor layer 401. The semiconductor layer 401 may include silicon, silicon germanium, gallium arsenide, germanium, silicon-on-insulator, germanium-on-insulator, or any other suitable material. In other implementations, the semiconductor device may not include the semiconductor layer.

In some implementations, the memory string 308 includes a channel structure that extends vertically through the stacked structure 410. In some implementations, the channel structure includes a channel hole filled with semiconductor material(s) (e.g., as a semiconductor channel) and dielectric material(s) (e.g., as a memory film). In some implementations, the semiconductor channel includes silicon, e.g., polysilicon. In some implementations, the memory film is a composite dielectric layer including a tunneling layer, a storage layer (also referred to as a “charge trapping/storage layer”), and a barrier layer. The channel structure may have a cylindrical shape (e.g., a pillar shape). According to some implementations, the semiconductor channel, the tunneling layer, the storage layer and the barrier layer are arranged radially from the center of the pillar toward the outer surface of the pillar in this order. The tunneling layer may include silicon oxide, silicon oxynitride, or any combination thereof. The storage layer may include silicon nitride, silicon oxynitride, or any combination thereof. The barrier layer may include silicon oxide, silicon oxynitride, a high-k dielectric, or any combination thereof. In an implementation, the memory film may include a composite layer of silicon oxide/silicon oxynitride/silicon oxide (ONO).

Referring back to FIG. 3, the peripheral circuit 302 may be coupled to the memory array 301 through bit lines 316, word lines 318, source lines 314, bottom select lines 315, and top select lines 313. The peripheral circuit 302 may include any suitable analog, digital, and mixed-signal circuits for facilitating operations of the memory array 301 by applying and sensing voltage signals and/or current signals to and from each target memory cell of the memory cells 306 through bit lines 316, word lines 318, source lines 314, bottom select lines 315 and top select lines 313. The peripheral circuit 302 may include various types of peripheral circuits formed using metal-oxide-semiconductor technologies.

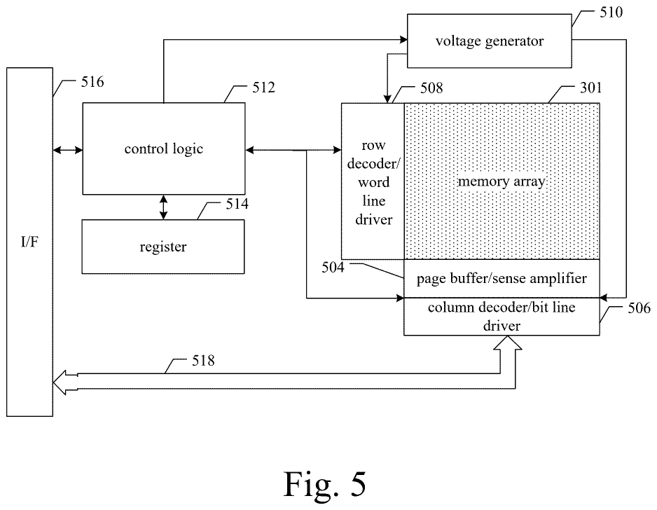

FIG. 5 is a schematic diagram of a semiconductor device including a peripheral circuit and a memory array according to an implementation of the present disclosure. The peripheral circuit 302 may include a page buffer/sense amplifier 504, a column decoder/bit line driver 506, a row decoder/word line driver 508, a voltage generator 510, a register 514 and a data bus 518. It should be understood that in some implementations, additional peripheral circuits not shown in FIG. 5 may be included as well.

A control logic 512 may be coupled to each peripheral circuit described above and configured to control the operation of each peripheral circuit. The register 514 may be coupled to the control logic 512 and includes status register, command register and address register for storing status information, command operation codes (OP code), and command addresses for controlling operations of each peripheral circuit.

The page buffer/sense amplifier 504 may be configured to read data from and program (write) data to the memory array 301 according to control signals from the control logic 512. In an implementation, the page buffer/sense amplifier 504 may store program data (written data) to be programmed into the memory cell 306 of the memory array 301. In another implementation, the page buffer/sense amplifier 504 may perform a program verify operation to ensure that the data has been properly programmed into the memory cell 306 coupled to the selected word line 318. Column decoder/bit line driver 506 may be configured to be controlled by the control logic 512 and select one or more NAND memory strings 308 by applying a bit line voltage generated from voltage generator 510.

The row decoder/word line driver 508 may be configured to be controlled by the control logic 512 and select/deselect memory blocks 304 of the memory array 301 and select/deselect word lines 318 of the memory block 304. The row decoder/word line driver 508 may be further configured to drive word lines 318 using word line voltages generated from the voltage generator 510. In some implementations, row decoder/word line driver 508 may also select/deselect and drive the bottom select line 315 and the top select line 313. As described in detail below, the row decoder/word line driver 508 is configured to perform program operations on the memory cells 306 coupled to selected word line(s) 318. The voltage generator 510 may be configured to be controlled by the control logic 512 and generate word line voltages (e.g., read voltages, program voltages, pass voltages, local voltages, verify voltages, input voltages, etc.), bit line voltages and source line voltages to be supplied to the memory array 301.

In conjunction with FIGS. 1 and 5, when performing the first operation with the second semiconductor structure, the control logic 512 may receive input data sent by an external device (e.g., a host), the digital-to-analog conversion circuit converts the input data to voltage signals that need to be applied on word lines or bit lines, the voltage generator 510 generates corresponding voltages that need to be applied on word lines or bit lines, the row decoder/word line driver 508 is configured to drive the selected word line using the word line voltage generated from the voltage generator 510, or the column decoder/bit line driver 506 is configured to drive the selected bit line using the bit line voltage generated from the voltage generator 510. The analog computing information obtained after the first operation is performed is transmitted to the analog-to-digital conversion circuit through the corresponding bit line, the first connection structure, the second bonding layer and the first bonding layer. The analog computing information is converted into digital information through the analog-to-digital conversion circuit. The resulting digital information is transmitted to the data processing circuit, and then the data processing circuit performs the second operation on the digital information. It should be noted that the digital-to-analog conversion circuit may be located in the third semiconductor structure and constitute a part of the peripheral circuit; or the digital-to-analog conversion circuit may be located in the first semiconductor structure.

In some implementations, for the computing in memory chip, a first operation of inputting data and a weight matrix needs to be implemented, the input data may be an input vector or an input matrix composed of a plurality of elements, the weight matrix is composed of a plurality of weights, and each element in the input data needs to perform a multiply-accumulate operation with a plurality of weights in the weight matrix to obtain a corresponding element in the output data.

To achieve the above operation functions, the memory array 301 may be configured to store a weight matrix; for instance, weights in the weight matrix may be written into the memory array 301 according to a certain mapping rule, and each memory cell 306 in the memory array 301 may be configured to store a weight. During the operation stage, the second semiconductor structure may receive input data from an external device. The input data may be an input vector or an input matrix composed of a plurality of elements, and each element in the input data may be converted into an input voltage via the digital-to-analog conversion circuit to be input into the memory array 301 by the bit line 316 or the word line 318.

In an implementation of the present disclosure, the analog computing information may be output via the bit line, or via the source terminal. That is, the bit line in the second semiconductor structure is the analog information output terminal, or the source terminal is the analog information output terminal. For ease of understanding, the following describes an implementation in which the bit line is the analog information output terminal as an example.

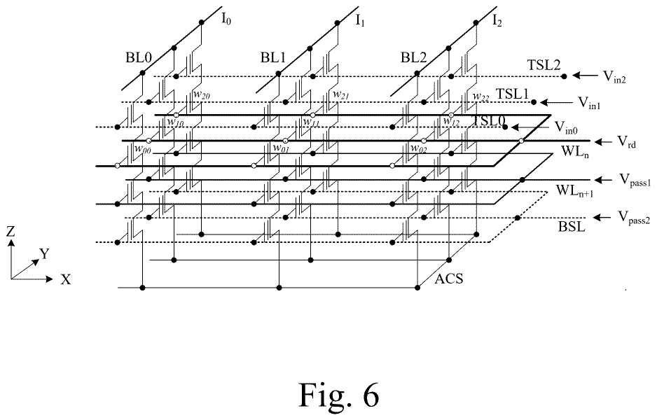

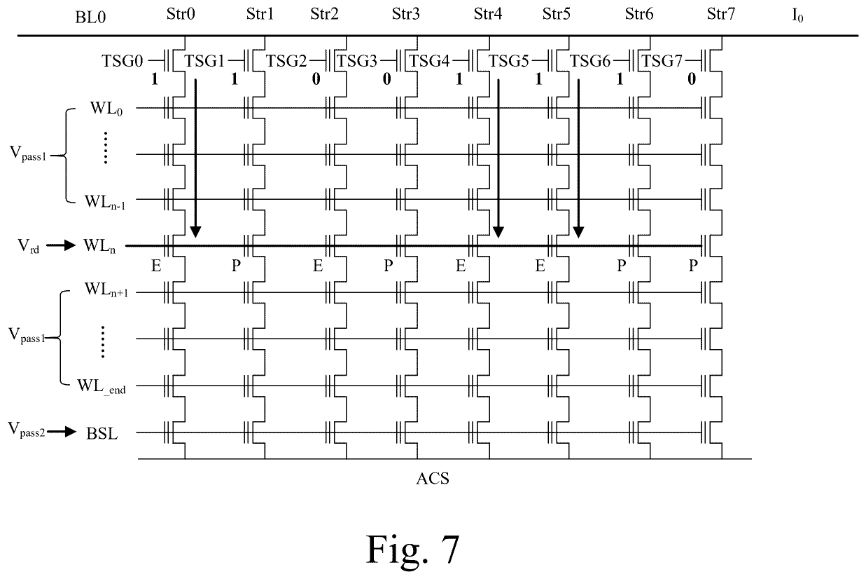

FIG. 6 is a schematic diagram where an input voltage is input to a memory array from a top select line according to an implementation of the present disclosure, and FIG. 7 is a schematic diagram of a plurality of memory strings coupled by a bit line according to an implementation of the present disclosure. It should be noted that the number of the bit lines, the number of the memory strings coupled by each bit line, and the number of the memory cells in each memory string shown in FIG. 6 and FIG. 7 are merely exemplary, and the number of various structures is not limited in the present disclosure. The process of the first operation is exemplarily described below with reference to FIG. 6 and FIG. 7 by taking the bit line as the analog information output terminal as an example.

Referring to FIG. 6, input voltages corresponding to elements in the input data may be input by a plurality of top select lines. During the first operation stage by using the memory array, the peripheral circuit is configured to apply a first read voltage V_{rd} to the target word line WLn coupled to the target memory block, and apply respective input voltages to the plurality of top select lines coupled to the target memory block; for example, the input voltages Vᵢₙ₀, Vᵢₙ₁ and Vᵢₙ₂ may be applied to the top select lines TSL0, TSL1 and TSL2 coupled to the target memory block, respectively. A first turn-on voltage may be applied to the non-target word lines coupled to the target memory block; for example, the first turn-on voltage Vₚₐₛₛ₁ may be applied to the word line WLn+1. A second turn-on voltage may be applied to the bottom select line coupled to the target memory block; for example, the second turn-on voltage Vₚₐₛₛ₂ may be applied to the bottom select line BSL. Analog computing information may be obtained by sensing currents on the bit lines coupled to the target memory block; for example, a sum of a product of an element corresponding to the input voltage Vᵢₙ₀ and the weight w₀₀, a product of an element corresponding to the input voltage Vᵢₙ₁ and the weight w₁₀, and a product of an element corresponding to the input voltage Vᵢₙ₂ and the weight W₂₀ may be obtained by sensing the current I₀ on the bit line BL0 and converting the current I₀. In some implementations, the first operation includes a multiply-accumulate operation.

In some implementations, the peripheral circuit is configured to apply respective program voltages to target word lines coupled to the target memory block to program memory cells coupled to the target word lines before performing the first operation with the memory array.

In an implementation, the memory cell in the target memory block is configured to store a bit of data, the plurality of memory cells in the target memory block have a first memory state and a second memory state, the threshold voltage of the memory cell having the first memory state is less than the threshold voltage of the memory cell having the second memory state, the first read voltage V_{rd} is greater than the threshold voltage of the memory cell having the first memory state, and is less than the threshold voltage of the memory cell having the second memory state. Here, the memory cell in the target memory block may be a single-level cell SLC storing one bit of data, the first memory state may be an erase state E, and the second memory state may be a program state P. The peripheral circuit may be configured to perform program operations on memory cells coupled to the target word line before performing the first operation, write weights to the memory cells according to a certain mapping rule; and for the single level cell, the process of weight writing includes applying respective program voltages to adjust threshold voltages of a portion of the memory cells coupled to the target word line to be within a range of a threshold voltage distribution corresponding to the second memory state.

In some implementations, referring to FIG. 7, taking the target memory block including eight memory strings coupled to the bit line BL0 as an example, four memory cells in the memory cells coupled to the target word line WLn are in the first memory state (erased state E), the other four memory cells are in the second memory state (programmed state P), the input data may be input from the eight top select lines TSL0 to TSL7.

For instance, the input data may be an input vector including eight elements, the eight elements may include five “1” and three “0”, the digital-to-analog conversion circuit may convert each element of the input vector into a corresponding voltage signal, convert the voltage signal by the voltage generator into an input voltage that needs to be applied on the top select line, and transfer the input voltage to the top select line through a driver coupled to the top select line. By way of example and not limitation, eight input voltages may be concurrently applied to the eight top select lines, respectively. The input voltages corresponding to “1” include Vᵢₙ₀, Vᵢₙ₁, Vᵢₙ₄, Vᵢₙ₅, and Vᵢₙ₆, so that the top select transistors TSG0, TSG1, TSG 4, TSG 5, and TSG 6 coupled to the top select lines TSL0, TSL1, TSL4, TSL5, and TSL6, respectively, may be turned on; and the input voltages corresponding to “0” include Vᵢₙ₂, Vᵢₙ₃, and Vᵢₙ₇, so that the top select transistors TSG2, TSG3, and TSG7 coupled to the top select lines TSL2, TSL3, and TSL7, respectively, may be turned off.

In an implementation, referring to FIG. 7, the current I₀ on the bit line BL0 is the sum of the output currents of the eight memory strings coupled to the bit line BL0, where input voltages on the top select lines coupled to the memory strings Str0, Str4 and Str5 cause the top select transistors TSG0, TSG4 and the TSG 5 to be in a turned-on state, and the memory cells in the memory strings Str0, Str4 and Str5 coupled to the target word line WLn have the first memory state (erase state E), and thus the memory strings Str0, Str4, and Str5 turn on, and currents greater than or equal to the preset current may be generated. The current I₀ on the bit line BL0 is substantially equal to the sum of the output currents of the memory strings Str0, Str4 and Str5, and a multiple of the current I₀ with respect to the current generated by any one of the memory strings Str0, Str4 and Str5 is approximately equal to three. If the weight value stored in the memory cell in the first memory state is equivalent to “1”, and the weight value stored in the memory cell in the second memory state is equivalent to “0”, the operation performed on the eight memory strings coupled to the bit line BL0 may be equivalent to: 1×1+1×0+0×1+0×0+1×1+1×1+1×0+0×0=3.

Based on the above implementation, when the memory strings in the target memory block that are coupled with the bit line BLx is Y+1, the Y+1 elements corresponding to the input voltages input by the Y+1 top select lines are α₀, α_{1,} . . . , α_{Y}, respectively, and the weights stored in the Y+1 memory cells coupled to the target word line WLn are w₀, w_{1,} . . . , w_{Y}, respectively, and the analog computing information equivalent to the multiple of the current on the bit line BLx with respect to the output current greater than or equal to the preset current may be α₀*w₀+α₁*w₁+ . . . +α_{Y}*w_{Y}.

In an implementation of the present disclosure, when the first operation needs to be performed by using the plurality of sub-memory planes, the first turn-on voltage may be applied to non-target word lines in the plurality of sub-memory planes at the same time, so that the voltage establishment stages of the first turn-on voltages applied on the non-target word lines coupled to different sub-memory planes may overlap, and compared with the manner of respectively applying the first turn-on voltage to non-target word lines coupled to different sub-memory planes in different operation stages, the overall operation time may be shortened, and the operation efficiency of performing the first operation by using the plurality of sub-memory planes may be improved.

Further, for each sub-memory plane, the first operation may be performed by using the plurality of memory blocks in the sub-memory plane at the same time, and the peripheral circuit may be configured to: apply first read voltages to the target word lines respectively coupled to the plurality of memory blocks of the sub-memory plane; apply respective input voltages to the plurality of top selection lines respectively coupled to the plurality of memory blocks of the sub-memory plane; and sense the currents on the bit lines coupled to the plurality of memory blocks of the sub-memory plane. For instance, the first read voltage Vrd may be concurrently applied to the target word lines respectively coupled to the memory block 0 to the memory block (N−1) in the memory plane 0; meanwhile, respective input voltages Vᵢₙ are applied to the plurality of top select lines respectively coupled to the memory block 0 to the memory block (N−1) in the memory plane 0, and the currents on the bit lines coupled to the memory block 0 to the memory block (N−1) in the memory plane 0 are sensed, and the current on the bit line is the analog computing information after the first operation is performed on all the memory strings coupled to the bit line. Therefore, the plurality of memory blocks can perform the first operation in parallel, so that the operation efficiency and the computing ability of the semiconductor device can be further improved.

FIG. 8 is a structural diagram of a semiconductor device according to an implementation of the present disclosure, and the semiconductor device 600 includes, but is not limited to, a three-dimensional NAND memory. It should be noted that the number of the sub-memory planes, the number of the bit lines, the number of the first connection structures 622, and the number of the second connection structures 624 shown in FIG. 8 are merely exemplary, and the number of various structures is not limited in the present disclosure.

Referring to FIG. 8, the second semiconductor structure 604 includes a memory array, a plurality of bit lines and a plurality of first connection structures 622, for example, four bit lines BL0 to BL3 are located on a side of the memory array facing away from the first semiconductor structure 602, and each of four bit lines BL0 to BL3 is connected to an analog-to-digital conversion circuit in the first semiconductor structure 602 through one of four first connection structures 622. In an implementation, the first connection structure 622 includes a through silicon contact (TSC), a first end of the first connection structure 622 is connected to a bit line, and a second end of the first connection structure 622 is connected to the second bonding layer 616, where the first end of the first connection structure 622 and the second end of the first connection structure 622 are opposite to each other along an extension direction of the first connection structures 622, and an extension direction of the first connection structures 622 is denoted as a Z direction in FIG. 8. Therefore, the bit line may be connected to the analog-to-digital conversion circuit through the first connection structure 622, the second bonding layer 616, and the first bonding layer (not shown in FIG. 8), so as to transmit the analog computing information to the analog-to-digital conversion circuit. Regarding the first bonding layer and the second bonding layer 616, it may refer to related descriptions of the first bonding layer 114 and the second bonding layer 116 in FIG. 1, respectively.

In some implementations, the memory array includes a plurality of sub-memory planes, the plurality of sub-memory planes are arranged at intervals along an extending direction of the bit lines, and at least one first connection structure located between two adjacent sub-memory planes. For example, the sub-memory plane 0 and the sub-memory plane 1 are arranged at an interval along the Y direction, and two first connection structures 622 connected to the bit line BL2 and the bit line BL3 are both located between the sub-memory plane 0 and the sub-memory plane 1. The first connection structure 622 connected to the bit line BL0 is located between the sub-memory plane 0 and another sub-memory plane adjacent to a left side of the sub-memory plane 0; or the first connection structure 622 connected to the bit line BL0 is located on the leftmost side of the plurality of sub-memory planes; that is, there is no other sub-memory plane on the left side of the sub-memory plane 0. The first connection structure 622 connected to the bit line BL1 is located between the sub-memory plane 1 and another sub-memory plane adjacent to a right side of the sub-memory plane 1; or the first connection structure 622 connected to the bit line BL1 is located on the rightmost side of the plurality of sub-memory planes, that is, there is no other sub-memory plane on the right side of the sub-memory plane 1.

It can be understood that FIG. 8 shows that a portion of the first connection structures 622 are located between two adjacent sub-memory planes, and the other portion of the first connection structures 622 are located on two opposite sides of the plurality of sub-memory planes along the Y direction, so that at least a portion of the bit lines can be led out to the first semiconductor structure 602 by using the space between two adjacent sub-memory planes, so that the arrangement of the plurality of first connection structures 622 may be optimized by reasonably utilizing space, and the occupied area of the plurality of first connection structures 622 can be reduced. Of course, in other implementations, the plurality of first connection structures 622 may be located between any two adjacent sub-memory planes.

Referring to FIG. 8, the second semiconductor structure 604 further includes a plurality of second connection structures 624, for example, four bit lines BL0 to BL3 are connected to peripheral circuits (not shown in FIG. 8) in the third semiconductor structure 606 through four second connection structures 624, respectively. In an implementation, the second connection structure 624 includes a TSC, a first end of the second connection structure 624 is connected to the bit line, and a second end of the second connection structure 624 is connected to the third bonding layer, where a first end of the second connection structure 624 and a second end of the second connection structure 624 are opposite to each other along an extending direction of the second connection structures 624. The extension direction of the second connection structures 624 is denoted as the Z direction in FIG. 8. Therefore, the bit line may be connected to the peripheral circuit through the second connection structure 624, the third bonding layer and the fourth bonding layer, so as to transmit information such as a read result, a program verification result or an erase verification result to the peripheral circuit. Regarding the third bonding layer and the fourth bonding layer, it may refer to related descriptions of the third bonding layer 118 and the fourth bonding layer 120 in FIG. 1, respectively.

In some implementations, the cross-sectional size of the first end of the first connection structure 622 is smaller than or equal to the cross-sectional size of the second end of the first connection structure 622; and the cross-sectional size of the first end of the second connection structure 624 is smaller than or equal to the cross-sectional size of the second end of the second connection structure 624. In an actual manufacturing process, after structures such as a memory array and bit lines are formed on the front surface of the second substrate, second connection holes exposing the first surfaces of the bit lines are formed by etching in a direction towards the front side of the second substrate, and a conductive material is filled into the second connection holes to form the second connection structures 624. Due to the large challenge of deep hole etching, the cross-sectional size of the bottom of the second connecting hole usually formed is smaller than or equal to the cross-sectional size of the top of the second connecting hole, so that the cross-sectional size of the first end of the second connection structure 624 is smaller than or equal to the cross-sectional size of the second end of the second connection structure 624.

After the second semiconductor structure 604 is bonded with the third semiconductor structure 606, the backside surface of the second substrate may be thinned, first connection holes exposing the second surfaces of the bit lines are formed by etching in a direction towards the backside surface of the thinned second substrate, a conductive material is filled into the first connection holes to form the first connection structures 622, and the first surface and the second surface of the bit line are opposite to each other in the Z direction. Similarly, due to the challenge of deep hole etching, the cross-sectional size of the bottom of the first connecting hole usually formed is smaller than or equal to the cross-sectional size of the top of the first connecting hole, so that the cross-sectional size of the first end of the first connection structure 622 is smaller than or equal to the cross-sectional size of the second end of the first connection structure 622.

In some implementations, the sub-memory plane includes a plurality of first memory blocks, and at least one of the first connection structures 622 extends through at least one of the first memory blocks. For example, a portion of the first memory blocks in the sub-memory plane is configured to store data, the other portion of the first memory blocks in the sub-memory plane is configured as dummy memory blocks, at least one of the first connection structures 622 may extend through the first memory blocks in the sub-memory plane configured as dummy memory blocks, and thus the bit lines may be led out by using the space occupied by the first memory blocks in the sub-memory plane configured as the dummy memory blocks; that is, the bit lines are led out by using the space occupied by the existing first memory blocks, and the planar size of the semiconductor device 600 is not increased. It should be noted that the structure of the dummy memory block may be substantially the same as the structure of the memory block, but the dummy memory block is not configured to store data, and the dummy memory block usually plays a role of supporting, balancing stress and the like.

In some implementations, the second semiconductor structure 604 further includes a second memory block located between two adjacent sub-memory planes, and the first connection structure 622 located between two adjacent sub-memory planes extends through the second memory block. For example, the second memory block may be configured as a dummy memory block, and at least one of the first connection structures 622 may extend through the dummy memory block between two adjacent sub-memory planes, so that the bit line may be led out by using the space occupied by the second memory block between two adjacent sub-memory planes; that is, the bit line is led out by using the space occupied by the existing second memory block, and the planar size of the semiconductor device 600 is not increased. It should be noted that structures of the second memory block and the first memory block may be substantially the same, and the second memory block may be used to physically separate two adjacent sub-memory planes. Of course, in other implementations, two adjacent sub-memory planes may be physically separated by a dielectric layer, and at least one of the first connection structures 622 may extend through the dielectric layer between two adjacent sub-memory planes.

In some implementations, the first semiconductor structure 602 further includes a control circuit (not shown) which may be configured to control the operation of the semiconductor device 600. That is, the control circuit may act as a memory controller for managing the storage and transmission of data in the bonded second semiconductor structure 604 and the third semiconductor structure 606 (hereinafter referred to as a bonded semiconductor structure) and an operation controller for managing the operation and transmission of data in the first semiconductor structure. It should be noted that the process node corresponding to the first semiconductor structure may be smaller than the process node corresponding to the third semiconductor structure; in this implementation, the control circuit is integrated into the first semiconductor structure 602 with a smaller process node and bonded with the bonding semiconductor structure, so that the planar size of the semiconductor device can be reduced, the integration level can be improved, and the data transmission rate can also be improved.

In some implementations, the control circuit is coupled to the bonded semiconductor structure and an external device (e.g., a host), and configured to control the bonded semiconductor structure. The control circuit can manage data stored in the bonded semiconductor structure and communicate with the external device. For example, the control circuit is further configured to control data transmission between the first semiconductor structure 602 and the bonded semiconductor structure. As another example, the control circuit is further configured to receive input data sent by the external device, and send the input data to the bonded semiconductor structure. Of course, in other implementations, some or all of the host may be integrated in the first semiconductor structure; for example, the host processor may be integrated in the first semiconductor structure.

In some implementations, the control circuit may also be configured to manage various functions regarding data stored in or to be stored in the bonded semiconductor structure, where the functions includes, but is not limited to, bad block management, garbage collection, logical-to-physical address translation, wear leveling, and the like. In some implementations, the control circuit is further configured to process an Error Correction Code (ECC) regarding data read from or written to the bonded semiconductor structure. In some implementations, the control circuit may also perform any other suitable functions, such as formatting the bonded semiconductor structure.

In some implementations, the first semiconductor structure 602 further includes a first interface circuit (not shown) configured to receive and transmit data between the semiconductor device 600 and the external device. For instance, the first interface circuit is configured to output the operation result after the data processing circuit performs the second operation to the external device. The interface protocol can be used as the first interface circuit between the control circuit and the external device, so that the control circuit may communicate with external devices through at least one of a variety of interface protocols, such as a USB protocol, an MMC protocol, a Peripheral Component Interconnect (PCI) protocol, a PCI Express (PCI-E) protocol, an Advanced Technology Attachment (ATA) protocol, a Serial ATA protocol, a parallel ATA protocol, a Small Computer Small Interface (SCSI) protocol, an Enhanced Small Disk Interface (ESDI) protocol, an Integrated Drive Electronics (IDE) protocol, a Firewire protocol, or the like. The first interface circuit herein may also be referred to as a front-end interface. In some implementations, the control circuit performs command/data interaction with the bonded semiconductor structure through a plurality of configured channels. These channels are also referred to as back-end interfaces.

In some implementations, the third semiconductor structure 606 further includes a second interface circuit (not shown); the third semiconductor structure 606 may be connected to the first semiconductor structure through the second interface circuit. That is, the second interface circuit herein is an interface coupled to the back-end interface of the control circuit, e.g., the second interface circuit may also be an interface through which the third semiconductor structure communicates with the first semiconductor structure. The second interface circuit may be coupled to the control logic 512 in FIG. 5 and act as a control buffer to buffer control commands received from a host (not shown) and relay them to the control logic 512 and to buffer status information received from the control logic 512 and relay it to the host. The second interface circuit may also be coupled to the column decoder/bit line driver 506 in FIG. 5 via the data bus 518 in FIG. 5 and act as a data I/O interface and data buffer to buffer data and relay the data to or from the memory array.

In some implementations, the second semiconductor structure 604 further includes a source layer (not shown) located between the memory array and the first semiconductor structure 602, and the source layer is connected to at least one of the peripheral circuit and the control circuit. For example, as shown in FIG. 8, the source layer may be located between the memory array and the conductive layer 626, the conductive layer 626 is located between the source layer and the second bonding layer 616; that is, the source layer is located on a side of the memory array close to the first semiconductor structure 602, source terminals of the memory strings described above may be connected to the source layer, and drain terminals of the memory strings may be connected to the bit lines.

In an implementation, the source layer may be connected to the peripheral circuit by the third connection structure 628 as described below, the third bonding layer, and the fourth bonding layer. In another implementation, the source layer may be connected to the control circuit through the conductive layer 626, the fourth connection structure 630 as described below, the second bonding layer 616 and the first bonding layer. The source layer may include one or more layers. For example, the source layer includes a conductive layer and a semiconductor layer. In an implementation, the material of the source layer includes a semiconductor material, including but not limited to intrinsic polysilicon, doped polysilicon (e.g., N-type doped silicon, P-type doped silicon), and the like. In some implementations, the source layer may extend laterally as an array common source ACS. That is, a plurality of memory strings in a same memory block are coupled to each other. However, in the case where the source layer is divided into multiple sub-source layers hereinafter, the sub-source layer may constitute a part of the sub-memory plane.

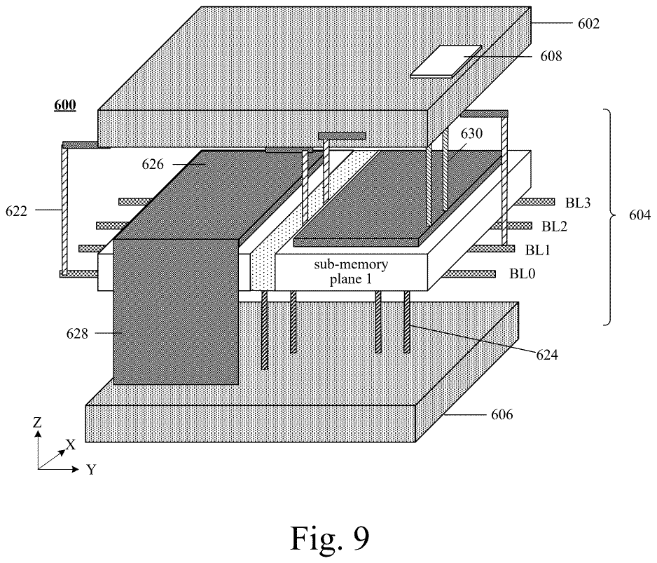

FIG. 9 is a structural diagram of another semiconductor device according to an implementation of the present disclosure. It should be noted that the implementation shown in FIG. 9 continues to use the same reference numbers for indicating the same structures as that of the foregoing implementations, and the same structures may refer to the related descriptions of the foregoing implementations, and details are not described again. In this implementation, only different structures are described in detail. For ease of illustration, an exemplary position of the analog-to-digital conversion circuit 608 in the first semiconductor structure 602 is shown in FIG. 9; however, it should be understood that, in an actual memory device, the analog-to-digital conversion circuit 608 is integrated in the first semiconductor structure 602.

In some implementations, the source layer includes a plurality of sub-source layers arranged at intervals along an extending direction of the bit lines, and each sub-source layer is correspondingly connected to one of the sub-memory planes. For example, the source layer includes two sub-source layers arranged at an interval along the Y direction, source terminals of the memory strings of the sub-memory plane 0 are connected to a sub-source layer, and source terminals of the memory strings of the sub-memory plane 1 are connected to another sub-source layer. In practical applications, the number of the sub-source layers is not limited to that shown in FIG. 9, and the number of the sub-source layers may be reasonably set according to the number of the sub-memory planes.

In some implementations, the second semiconductor structure 604 further includes a third connection structure 628 and a fourth connection structure 630; the third connection structure 628 is located between the first sub-source layer of the plurality of sub-source layers and the third semiconductor structure 606, and the first sub-source layer is connected to the peripheral circuit through the third connection structure 628; the fourth connection structure 630 is located between the second sub-source layer of the plurality of sub-source layers and the first semiconductor structure 602, and the second sub-source layer is connected to the control circuit through the fourth connection structure 630.

For example, the sub-source layer connected to source terminals of the memory strings of the sub-memory plane 0 in FIG. 9 may be the first sub-source layer, and the sub-source layer connected to source terminals of the memory strings in the sub-memory plane 1 in FIG. 9 may be the second sub-source layer.

In some implementations, the peripheral circuit may be coupled to the sub-memory plane 0 through the first sub-source layer, and the control circuit may be coupled to the sub-memory plane 1 through the second sub-source layer. For example, if the second sub-source layer is an analog signal output terminal, the control circuit may control the second sub-source layer to transmit the analog computing information obtained by performing the first operation on the sub-memory plane 1 to the analog-to-digital conversion circuit 608, thereby reducing the transmission distance of the signal. It may be understood that the sub-source layer in the plurality of sub-source layers connected to the peripheral circuit is the first sub-source layer, and the sub-source layer in the plurality of sub-source layers connected to the control circuit is the second sub-source layer. Of course, in other implementations, the plurality of sub-source layers may be connected to the peripheral circuit through the plurality of third connection structures 628, respectively.

In some implementations, the sub-memory plane connected to the first sub-source layer has a first side and a second side opposite to each other along an arrangement direction of the plurality of bit lines, the third connection structure 628 is located on the first side or the second side of the sub-memory plane connected to the first sub-source layer, and an arrangement direction of the plurality of bit lines intersects with an extension direction of the bit lines. FIG. 9 shows that the third connection structure 628 is located on a side of the four bit lines BL0 to BL3 opposite each other in the X direction; that is, the third connection structure 628 is located on the side of the plurality of bit lines opposite each other in the X direction, so that it can be avoided that the connection structures on two opposite sides of the bit line along the Y direction are arranged too densely, and the arrangement of the connection structures in the semiconductor device 600 can be optimized. The arrangement direction of the plurality of bit lines is denoted as the X direction in FIG. 9, and the extension direction of the bit lines is denoted as Y direction in FIG. 9. It should be noted that the third connection structure 628 as shown in FIG. 9 is merely exemplary, the third connection structure 628 may also have other shapes, and the third connection structure 628 may also include a TSC.

In some implementations, the second semiconductor structure 604 further includes a plurality of conductive layers 626 located between the source layer and the first semiconductor structure 602 and arranged at intervals along an extending direction of the bit lines, the first sub-source layer is connected to the third connection structure 628 through a conductive layer of the conductive layers 626, and the second sub-source layer is connected to the fourth connection structure 630 through another conductive layer of the conductive layers 626.

For example, FIG. 9 shows two conductive layers 626 arranged at an interval along the Y direction; the first sub-source layer is connected to a conductive layer 626 which is connected to the third bonding layer through the third connection structure 628. The second sub-source layer is connected to another conductive layer 626 which is connected to the second bonding layer 616 through the fourth connection structure 630. In practical applications, the number of the conductive layers 626 is not limited to that shown in FIG. 9, and the number of the conductive layers 626 may be reasonably set according to the number of the sub-source layers.

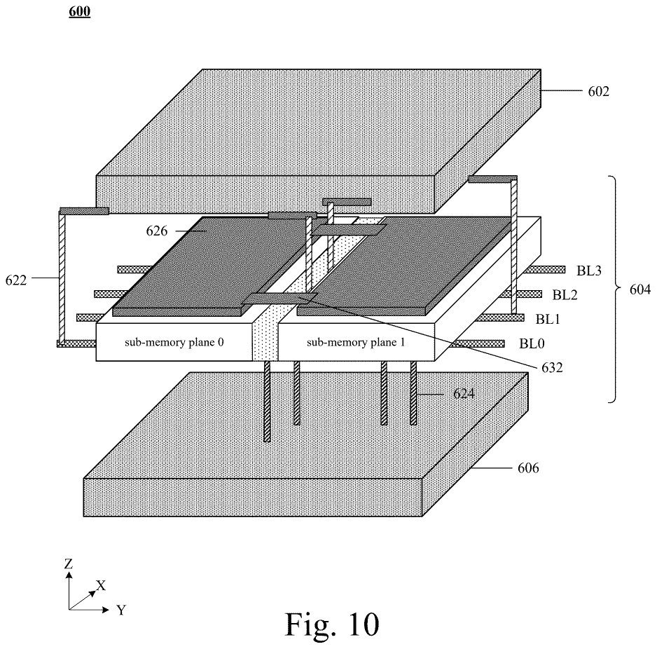

FIG. 10 is a structural diagram of still another semiconductor device 600 according to an implementation of the present disclosure. It should be noted that the implementation shown in FIG. 10 continues to use the same reference numbers for indicating the same structures as that of the foregoing implementations, and the same structures may refer to the related descriptions of the foregoing implementations, and details are not described again. In this implementation, only different structures are described in detail.

In some implementations, the second semiconductor structure 604 further includes at least one connection portion 632 located between two adjacent conductive layers 626, and two opposite ends of the connection portion 632 along an extension direction of the bit lines are respectively connected to two adjacent conductive layers 626. For example, two first connection portions 632 are shown in FIG. 10, so that two adjacent conductive layers 626 can be connected by using a space between two adjacent sub-memory planes. It should be noted that the number of the first connection portions 632 is not limited to that shown in FIG. 10, and the first connection structure 622 and the connection portion 632 located between two adjacent sub-memory planes are isolated from each other.

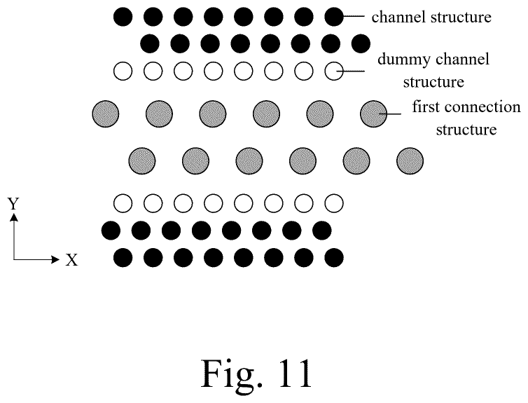

FIG. 11 is a top view of channel structures, dummy channel structures and first connection structures 622 according to an implementation of the present disclosure. Referring to FIG. 11, the channel structures located on two opposite sides of the first connection structures 622 in the Y direction belong to two sub-memory planes, respectively, the dummy channel structures located between the first connection structures 622 and the channel structures belong to the first memory block configured as the dummy memory block as described above or the second memory block, the first connection structures 622 are formed by the space occupied by the dummy memory blocks in the semiconductor device 600; the arrangement of the plurality of first connection structures 622 may be optimized by reasonably utilizing the space, and the occupied area of the plurality of first connection structures 622 is reduced. It should be noted that the structure of the dummy channel structure may be substantially the same as the structure of the channel structure, but dummy memory cells corresponding to the dummy channel structures are not used to store data, and the dummy channel structures usually play a role of supporting, balancing stress and the like. Regarding the channel structure, it may refer to the related descriptions of FIG. 4.

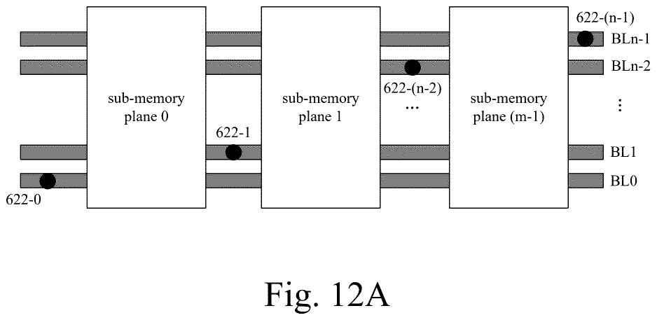

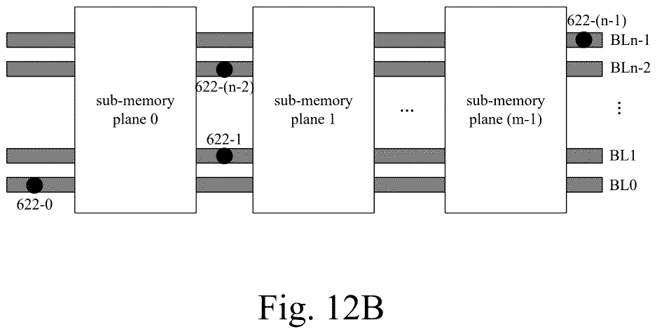

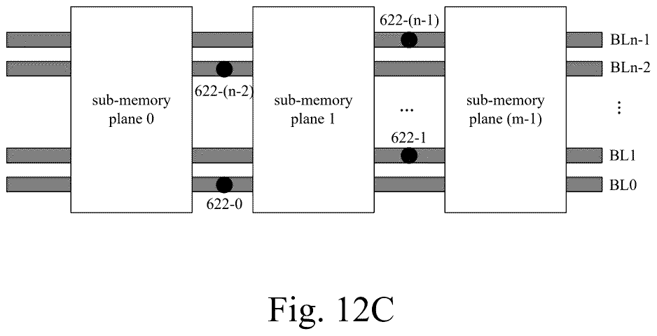

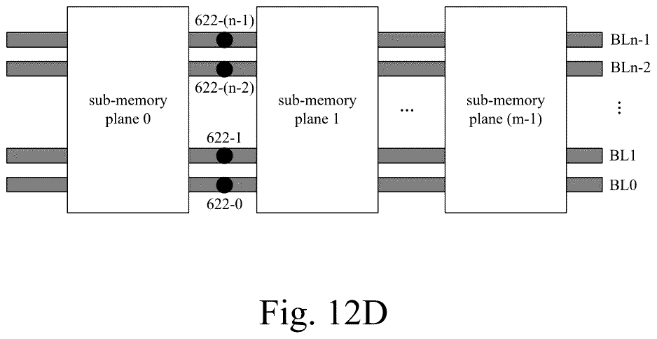

FIGS. 12A-12D are schematic diagrams of arrangements of first connection structures 622 according to implementations of the present disclosure. For ease of understanding, m sub-memory planes, n bit lines, and n first connection structures 622 are shown in FIGS. 12A-12D, where both m and n are integers greater than 1.

In some implementations, a portion of the plurality of first connection structures 622 are located between two adjacent sub-memory planes, and another portion of the plurality of first connection structures 622 are located on two opposite sides of the plurality of sub-memory planes along the extension direction of the bit lines.

For example, FIGS. 12A-12B show that the first connection structure 622-0 connected to bit line BL0 and the first connection structure 622-(n−1) connected to bit line BLn-1 are on two opposite sides of the sub-memory plane 0 to the sub-memory plane (m−1) along the extension direction of the bit lines. The first connection structure 622-1 connected to bit line BL1 in FIG. 12A is located between the sub-memory plane 0 and sub-memory plane 1, and the first connection structure 622-(n−2) connected to bit line BLn-2 is located between the sub-memory plane 1 and the sub-memory plane (m−1). The first connection structure 622-1 connected to bit line BL1 and the first connection structure 622-(n−2) connected to the bit line BLn-2 in FIG. 12B are both located between the sub-memory plane 0 and the sub-memory plane 1.

In some implementations, any one of the plurality of first connection structures 622 is located between two adjacent sub-memory planes. For example, FIG. 12C shows that the first connection structure 622-0 connected to bit line BL0 and the first connection structure 622-(n−2) connected to bit line BLn-2 are both located between the sub-memory plane 0 and the sub-memory plane 1, and the first connection structure 622-1 connected to bit line BL1 and the first connection structure 622-(n−1) connected to bit line BLn-1 are both located between the sub-memory plane 1 and the sub-memory plane (m−1). As another example, FIG. 12D illustrates that the first connection structure 622-0 connected to bit line BL0, the first connection structure 622-1 connected to bit line BL1, the first connection structure 622-(n−1) connected to bit line BLn-1 and the first connection structure 622-(n−2) connected to bit line BLn-2 are all located between the sub-memory plane 0 and the sub-memory plane 1.

It should be noted that FIGS. 12A-12D show several examples of the arrangements of the plurality of first connection structures 622, however, the arrangements of the plurality of first connection structures 622 are not limited to that shown in FIGS. 12A-12D. In practical applications, the plurality of first connection structures 622 should be reasonably arranged in comprehensive consideration of the feature size of the first connection structure 622, the distance between two adjacent sub-memory planes, and the distance between two adjacent bit lines, so as to reduce the problems of short circuit or large parasitic capacitance caused by a relatively short distance between two adjacent first connection structures 622.

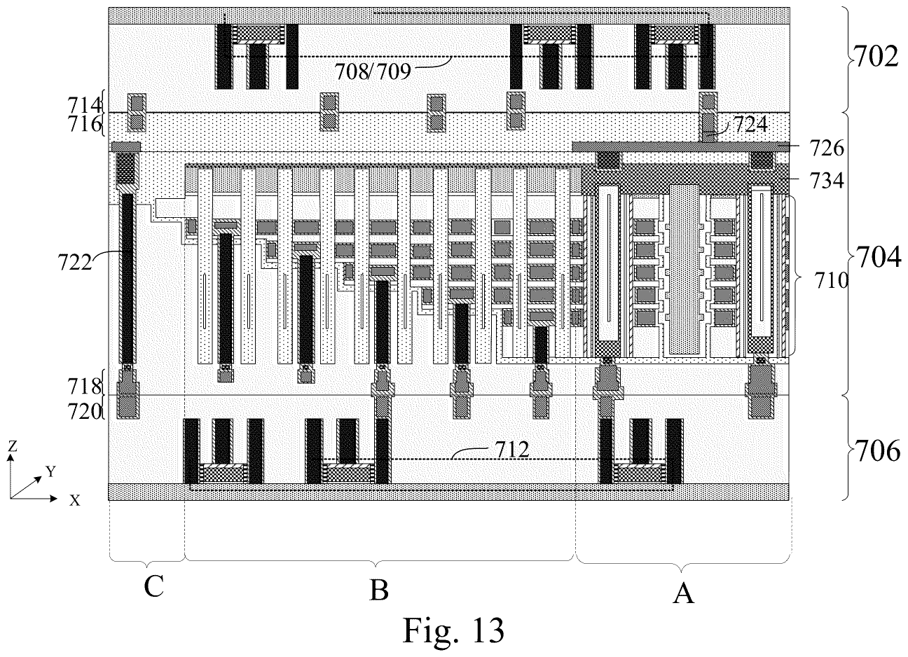

FIG. 13 is a structural diagram of a semiconductor device according to an implementation of the present disclosure. Referring to FIG. 13, the semiconductor device 100 includes a core region A, a connection region B and a peripheral region C. The semiconductor device 100 includes a first semiconductor structure 702, a second semiconductor structure 704 and a third semiconductor structure 706, where the first semiconductor structure 702 is bonded with a first side of the second semiconductor structure 704, the third semiconductor structure 706 is bonded with a second side of the second semiconductor structure 704, and the first side of the second semiconductor structure 704 and the second side of the second semiconductor structure 704 are two opposite sides of the second semiconductor structure 704 in the Z direction.

The first semiconductor structure 702 includes an analog-to-digital conversion circuit 708 and a data processing circuit 709. Regarding the analog-to-digital conversion circuit 708 and the data processing circuit 709, references may be made to the related descriptions of the analog-to-digital conversion circuit 108 and the data processing circuit 109 in FIG. 1.

The second semiconductor structure 704 includes a stacked structure 710 and memory strings extending through the stacked structure 710, where source terminals of the memory strings are connected to the semiconductor material layer 734, and drain terminals of the memory strings are connected to the bit lines. Regarding the stacked structure 710, references may be made to the related descriptions of the stacked structure 410 in FIG. 4, and regarding the memory string, references may be made to the related descriptions of the memory string 308 in FIG. 3 and FIG. 4.

The third semiconductor structure 706 includes a peripheral circuit 712, and regarding the peripheral circuit 712, references may be made to the related descriptions of the peripheral circuit 112 in FIG. 1 and the related descriptions of FIG. 5.

In some implementations, the first semiconductor structure 702 and the second semiconductor structure 704 may be vertically connected by bonding. As an example, referring to FIG. 13, the first semiconductor structure 702 includes a first bonding layer 714, the second semiconductor structure 704 includes a second bonding layer 716, and the second bonding layer 716 is bonded to the first bonding layer 714, so that the first semiconductor structure 702 and the second semiconductor structure 704 are vertically connected. Regarding the first bonding layer 714 and the second bonding layer 716, references may be made to the related descriptions of the first bonding layer 114 and the second bonding layer 116 in FIG. 1.

In some implementations, the second semiconductor structure 704 and the third semiconductor structure 706 may be vertically connected by bonding. As an example, referring to FIG. 13, the second semiconductor structure 704 includes a third bonding layer 718, and the third semiconductor structure 706 includes a fourth bonding layer 720, and the fourth bonding layer 720 is bonded to the third bonding layer 718, so that the second semiconductor structure 704 and the third semiconductor structure 706 are vertically connected. Regarding the third bonding layer 718 and the fourth bonding layer 720, references may be made to the related descriptions of the third bonding layer 118 and the fourth bonding layer 120 in FIG. 1.

In some implementations, the second semiconductor structure 704 further includes a conductive layer 726 located between the semiconductor material layer 734 and the second bonding layer 716 and coupled to the semiconductor material layer 734, and the semiconductor material layer 734 may be connected to the peripheral circuit 712 or the control circuit in the first semiconductor structure 702 through the conductive layer 726. For example, the semiconductor material layer 734 may be connected to the peripheral circuit 712 through the conductive layer 726, the conductive structure 722 (for example, referring to the third connection structure 628 in FIG. 9), the third bonding layer 718 and the fourth bonding layer 720. As another example, the semiconductor material layer 734 may be connected to the control circuit through the conductive layer 726, the conductive structure 724 (for example, referring to the fourth connection structure 630 in FIG. 9), the second bonding layer 716 and the first bonding layer 714.

The implementations of the present disclosure further provide a semiconductor device. The semiconductor device includes a first semiconductor structure and a second semiconductor structure, the first semiconductor structure is bonded with a first side of the second semiconductor structure; the first semiconductor structure includes an analog-to-digital conversion circuit; the second semiconductor structure includes a plurality of sub-memory planes, a plurality of bit lines and a plurality of first connection structures, the plurality of sub-memory planes are located between the plurality of bit lines and the first side of the second semiconductor structure and are arranged at intervals along an extension direction of the bit lines, and at least one of the first connection structures is located between two adjacent sub-memory planes and respectively connected to the bit line and the analog-to-digital conversion circuit.

In some implementations, the sub-memory plane includes a plurality of first memory blocks, and at least one of the first connection structures extends through at least one of the first memory blocks.

In some implementations, the second semiconductor structure further includes a second memory block located between two adjacent sub-memory planes, where the first connection structure located between two adjacent sub-memory planes extends through the second memory block.

In some implementations, the semiconductor device further includes a third semiconductor structure bonded with a second side of the second semiconductor structure, and the second side of the second semiconductor structure and the first side of the second semiconductor structure are opposite to each other along an extension direction of the first connection structures; the third semiconductor structure includes a peripheral circuit; the second semiconductor structure further includes a plurality of second connection structures located between the plurality of bit lines and the third semiconductor structure, and each bit line is connected to the peripheral circuit through one of the second connection structures.

In some implementations, the first semiconductor structure further includes a control circuit; the second semiconductor structure further includes a source layer located between the plurality of sub-memory planes and the first semiconductor structure, where the source layer is connected to at least one of the peripheral circuit and the control circuit.

In some implementations, the source layer includes a plurality of sub-source layers arranged at intervals along the extending direction of the bit lines, where each of the sub-source layers is correspondingly connected to one of the sub-memory planes; the second semiconductor structure further includes a third connection structure and a fourth connection structure; the third connection structure is located between a first sub-source layer of the plurality of sub-source layers and the third semiconductor structure, where the first sub-source layer is connected to the peripheral circuit through the third connection structure; the fourth connection structure is located between a second sub-source layer of the plurality of sub-source layers and the first semiconductor structure, where the second sub-source layer is connected to the control circuit through the fourth connection structure.

In some implementations, the sub-memory plane connected to the first sub-source layer has a first side and a second side opposite to each other along an arrangement direction of the plurality of bit lines, where the third connection structure is located on the first side or the second side of the sub-memory plane connected to the first sub-source layer, and the arrangement direction of the plurality of bit lines intersects with an extension direction of the bit lines.

In some implementations, the second semiconductor structure further includes a plurality of conductive layers located between the source layer and the first semiconductor structure and arranged at intervals along the extending direction of the bit lines, where the first sub-source layer is connected to the third connection structure through a conductive layer of the conductive layers, and the second sub-source layer is connected to the fourth connection structure through another conductive layer of the conductive layers.

In some implementations, the second semiconductor structure further includes at least one connection portion located between two adjacent conductive layers, where two opposite ends of the connection portion along the extension direction of the bit lines are respectively connected to the two adjacent conductive layers.

In some implementations, the first semiconductor structure includes a first bonding layer located between the second semiconductor structure and the analog-to-digital conversion circuit; the second semiconductor structure includes a second bonding layer and a third bonding layer, the second bonding layer is located between the plurality of sub-memory planes and the first bonding layer, the third bonding layer is located between the plurality of second connection structures and the third semiconductor structure, where the second bonding layer is bonded to the first bonding layer; the third semiconductor structure further includes a fourth bonding layer located between the peripheral circuit and the third bonding layer, where the fourth bonding layer is bonded to the third bonding layer.

In some implementations, a first end of the first connection structure is connected to the bit line, a second end of the first connection structure is connected to the second bonding layer, where the first end of the first connection structure and the second end of the first connection structure are opposite to each other along an extending direction of the first connection structures; a first end of the second connection structure is connected to the bit line, and a second end of the second connection structure is connected to the third bonding layer, where the first end of the second connection structure and the second end of the second connection structure are opposite to each other along an extending direction of the second connection structures.

In some implementations, the cross-sectional size of the first end of the first connection structure is smaller than or equal to the cross-sectional size of the second end of the first connection structure; and the cross-sectional size of the first end of the second connection structure is smaller than or equal to the cross-sectional size of the second end of the second connection structure.

In some implementations, any one of the plurality of first connection structures is located between two adjacent sub-memory planes.

In some implementations, a portion of the plurality of first connection structures are located between two adjacent sub-memory planes, and another portion of the plurality of first connection structures are located on two opposite sides of the plurality of sub-memory planes along the extension direction of the bit lines.

In some implementations, the semiconductor device includes a three-dimensional NAND memory.

Herein, the structures and other details of the first semiconductor structure, the second semiconductor structure and the third semiconductor structure are similar to those in the foregoing semiconductor device, and details are not described herein again for brevity.

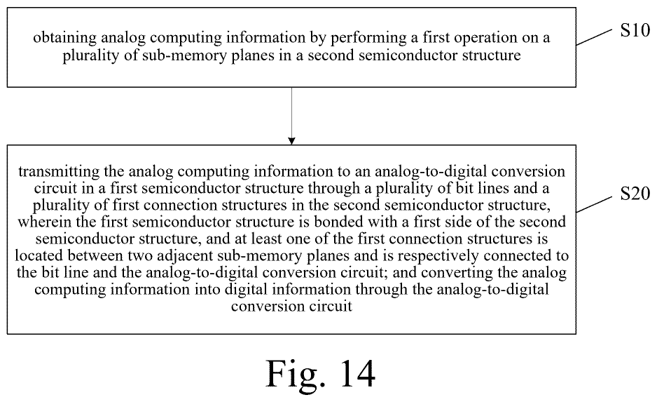

Based on the above semiconductor device, an implementation of the present disclosure provides a method of operating a semiconductor device. FIG. 14 is a flow diagram of a method of operating a semiconductor device according to an implementation of the present disclosure. As shown in FIG. 14, the method of operating the semiconductor device may include, e.g., operations S10 and S20.

At operation S10, the method may include obtaining analog computing information by performing a first operation on a plurality of sub-memory planes in a second semiconductor structure.

At operation S20, the method may include transmitting the analog computing information to an analog-to-digital conversion circuit in a first semiconductor structure through a plurality of bit lines and a plurality of first connection structures in the second semiconductor structure, where the first semiconductor structure is bonded with a first side of the second semiconductor structure, and at least one of the first connection structures is located between two adjacent sub-memory planes and respectively connected to the bit line and the analog-to-digital conversion circuit; and converting the analog computing information into digital information through the analog-to-digital conversion circuit.

In some implementations, the above method of operating further includes performing a second operation on the digital information through a data processing circuit in the first semiconductor structure, where the data processing circuit is connected to the analog-to-digital conversion circuit.

In some implementations, the first operation includes a multiply-accumulate operation; and the second operation includes one or more of a compensation, an activation, a shift or a pooling operation.

Based on the foregoing semiconductor device, an implementation of the present disclosure provides a package structure. The package structure includes a package substrate, the semiconductor device according to any one of the above implementations and an encapsulation layer, where the semiconductor device is located on a side of the package substrate, and the encapsulation layer encapsulates the semiconductor device.

In some implementations, the package substrate includes a substrate and a redistribution layer (interposer) formed on the substrate, a connection circuit is formed in the redistribution layer, and the semiconductor device is located on a side of the redistribution layer away from the substrate.

Based on the foregoing semiconductor device, an implementation of the present disclosure provides a system. The system includes the semiconductor device of any of the above implementations; and a controller coupled to the semiconductor device; the controller is configured to transmit data to and receive data from the semiconductor device.

Here, the structure of the semiconductor device may refer to the above implementations, and since the present system adopts all the technical solutions of all the above implementations, all the beneficial effects brought by the technical solutions of the above implementations are at least provided, which will not be repeated here.

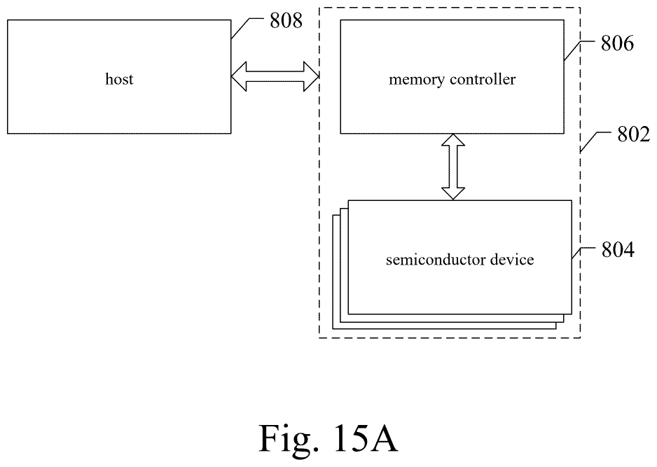

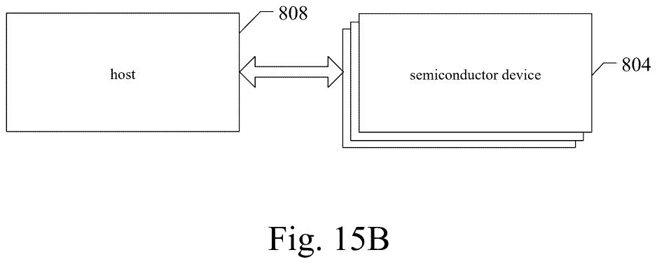

In some implementations, the system in the foregoing implementation may include the memory system 802 shown in FIG. 15A, the memory system 802 includes a memory controller 806 and a semiconductor device 804 coupled to the memory controller 806, the semiconductor device 804 may include the semiconductor device 100 or the semiconductor device 600 in the foregoing implementations, and the processor in the memory controller 806 may control the semiconductor device 804 to perform parallel computing.

According to some implementations, as shown in FIG. 15A, the memory controller 806 is coupled to the semiconductor device 804 and the host 808 and is configured to control operations of the semiconductor device 804, such as read, erase, program, computing operations. The memory controller 806 may manage data stored in the semiconductor device 804 and communicate with the host 808.

In some other implementations, the system in the foregoing implementation may include a system as shown in FIG. 15B, the system includes a host 808 and a semiconductor device 804 coupled to the host 808, the host 808 may include a GPU, the semiconductor device 804 may include the semiconductor device 100 or the semiconductor device 600 in the foregoing implementations, and the GPU in the host 808 may control the semiconductor device 804 to perform parallel computing.

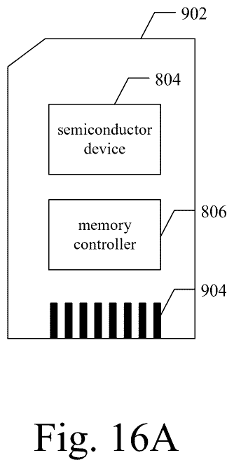

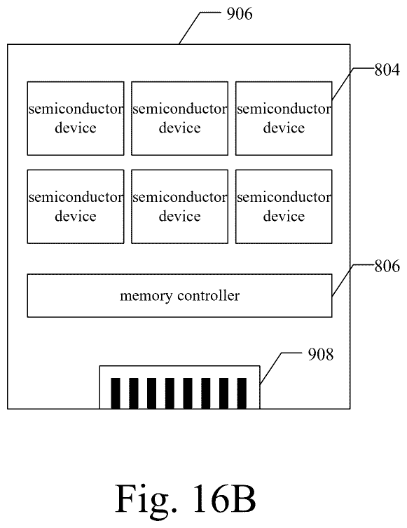

In an implementation as shown in FIG. 16A, the system may be integrated into the memory card 902, the semiconductor device in the system may be the semiconductor device 804 in the memory card 902, and the controller in the system may be the memory controller 806 in the memory card 902. The memory card 902 may be one of a compact flash memory card, a smart media card (SMC), a memory stick (MS), a multimedia card (MMC) (for example, an RS-MMC, an MMCmicro, an eMMC, or the like), a secure digital card (for example, a Mini SD card, a Micro SD card, an SDHC card, or the like), and a universal flash memory card. The memory card 902 may also include a memory card connector 904 that couples the memory card 902 with a host. In another implementation as shown in FIG. 16B, the system may be integrated into a solid state disk (SSD) 906, the semiconductor device in the system may be the semiconductor device 804 in the solid state disk 906, and the controller in the system may be the memory controller 806 in the solid state disk 906. The solid state disk 906 may further include a solid state disk connector 908 that couples the solid state disk 906 with the host end devices. In some implementations, the storage capacity and/or operating speed of solid state disk 906 is greater than the storage capacity and/or operating speed of memory card 902.

In some other implementations, the system may be integrated in the terminal device, the controller may be a central processing unit (CPU) of the terminal device, and the terminal device may include, but is not limited to, a mobile phone, a smart television, a smart speaker, a wearable device, a tablet computer, a desktop computer, a computer integrated machine, a handheld computer, a notebook computer, a server, an ultra-mobile personal computer (UMPC), a netbook, a personal digital assistant (PDA), a laptop, a mobile computer, an augmented reality (AR) device, a virtual reality (VR) device, an artificial intelligence (AI) device, or the like.

In some implementations, the system may be configured to implement various complex algorithms and data processing tasks. In an implementation, the system may be used in the field of artificial intelligence, such as machine learning, deep learning, neural networks, convolutional neural networks, and the like.

Based on the foregoing semiconductor device and the method of operating thereof, an implementation of the present disclosure provides a computer-readable storage medium on which a computer program stores, when the computer program is executed by a processor, the method of operating of any one of the foregoing implementations is implemented.

Herein, all or part of the processes in the method of operating in the foregoing implementations may be implemented by using a computer program to instruct related hardware, and the computer program may be stored in a computer-readable storage medium, the computer program, when executed, may include processes of the implementations of the foregoing methods. The storage medium may include a ferromagnetic random access memory (FRAM), a read-only memory (ROM), a programmable read-only memory (PROM), an erasable programmable read-only memory (EPROM), an electrically erasable programmable read-only memory (EEPROM), a flash memory, a magnetic surface memory, an optical disk, a compact disc read-only memory (CD-ROM), and the like; and the storage medium may further include a combination of the foregoing types of memories.

The features disclosed in the several apparatus implementations according to the present disclosure may be arbitrarily combined without conflict to obtain new apparatus implementations.

The method disclosed in the several method implementations according to the present disclosure may be arbitrarily combined without conflict to obtain new method implementations.

It should be understood that “one implementation” or “an implementation” mentioned throughout the specification means that particular features, structures, or characteristics related to the implementations are included in at least one implementation of the present disclosure. Thus, “in one implementation” or “in an implementation” appearing throughout the specification need not necessarily refer to the same implementation. Further, these particular features, structures, or characteristics may be incorporated in one or more implementations in any suitable manner. It should be understood that, in various implementations of the present disclosure, the serial numbers of the foregoing processes do not mean the order of execution, and the execution sequence of each process should be determined by its function and internal logic, and should not constitute any limitation on the implementation process of the implementations of the present disclosure. The foregoing serial numbers of the implementations of the present disclosure are merely for description, and do not represent the advantages or disadvantages of the implementations.

It should be noted that, in this specification, the terms “including”, “including”, or any other variant thereof are intended to cover a non-exclusive inclusion, such that a process, method, article, or apparatus that includes a series of elements includes not only those elements but also other elements not explicitly listed, or further includes elements inherent to such process, method, article, or apparatus. Without further restriction, the elements defined by the statement “include a . . . ” do not preclude the presence of additional identical elements in the process, method, article, or apparatus that includes the element.

The foregoing is only implementation of this disclosure, but the protection scope of the present disclosure is not limited thereto, and any change or replacement that can be easily conceived by those skilled in the art within the technical scope disclosed in the present disclosure should be covered within the protection scope of the present disclosure.

What is claimed is:

1. A semiconductor device, comprising:
a first semiconductor structure and a second semiconductor structure; wherein:
the first semiconductor structure is bonded with a first side of the second semiconductor structure;
the first semiconductor structure comprises an analog-to-digital conversion circuit; and
the second semiconductor structure comprises a memory array, a plurality of bit lines and a plurality of first connection structures, the memory array is located between the plurality of bit lines and the first side of the second semiconductor structure, the plurality of first connection structures are located between the plurality of bit lines and the first semiconductor structure, and each of the bit lines is connected to the analog-to-digital conversion circuit through one of the first connection structures.

2. The semiconductor device according to claim 1, wherein:
the memory array comprises a plurality of sub-memory planes arranged at intervals along an extending direction of the bit lines; and
at least one of the first connection structures is located between two adjacent sub-memory planes.

3. The semiconductor device according to claim 2, wherein:
the sub-memory plane comprises a plurality of first memory blocks; and
at least one of the first connection structures extends through at least one of the first memory blocks.

4. The semiconductor device according to claim 2, wherein:
the second semiconductor structure further comprises a second memory block located between two adjacent sub-memory planes; and
the first connection structure located between the two adjacent sub-memory planes extends through the second memory block.

5. The semiconductor device according to claim 2, further comprising:
a third semiconductor structure bonded with a second side of the second semiconductor structure;
wherein the second side of the second semiconductor structure and the first side of the second semiconductor structure are opposite to each other along an extension direction of the first connection structures;
wherein the third semiconductor structure comprises a peripheral circuit;
wherein the second semiconductor structure further comprises a plurality of second connection structures located between the plurality of bit lines and the third semiconductor structure; and
wherein each of the bit lines is connected to the peripheral circuit through one of the second connection structures.

6. The semiconductor device according to claim 5, wherein:
the first semiconductor structure further comprises a control circuit;
the second semiconductor structure further comprises a source layer located between the memory array and the first semiconductor structure; and
the source layer is connected to at least one of the peripheral circuit and the control circuit.

7. The semiconductor device according to claim 6, wherein:
the source layer comprises a plurality of sub-source layers arranged at intervals along the extending direction of the bit lines;
each of the sub-source layers is correspondingly connected to one of the sub-memory planes;
the second semiconductor structure further comprises a third connection structure and a fourth connection structure;
the third connection structure is located between a first sub-source layer of the plurality of sub-source layers and the third semiconductor structure;
the first sub-source layer is connected to the peripheral circuit through the third connection structure;
the fourth connection structure is located between a second sub-source layer of the plurality of sub-source layers and the first semiconductor structure; and
the second sub-source layer is connected to the control circuit through the fourth connection structure.

8. The semiconductor device according to claim 7, wherein:
the sub-memory plane connected to the first sub-source layer has a first side and a second side opposite to each other along an arrangement direction of the plurality of bit lines;
the third connection structure is located on the first side or the second side of the sub-memory plane connected to the first sub-source layer; and
the arrangement direction of the plurality of bit lines intersects with an extension direction of the bit lines.

9. The semiconductor device according to claim 7, wherein:
the second semiconductor structure further comprises a plurality of conductive layers located between the source layer and the first semiconductor structure and arranged at intervals along the extending direction of the bit lines;
the first sub-source layer is connected to the third connection structure through one of the conductive layers; and
the second sub-source layer is connected to the fourth connection structure through another conductive layer of the conductive layers.

10. The semiconductor device according to claim 9, wherein:
the second semiconductor structure further comprises at least one connection portion, the connection portion is located between two adjacent conductive layers; and
two opposite ends of the connection portion along the extension direction of the bit lines are respectively connected to the two adjacent conductive layers.

11. The semiconductor device according to claim 5, wherein:
the first semiconductor structure comprises a first bonding layer;
the first bonding layer is located between the second semiconductor structure and the analog-to-digital conversion circuit;
the second semiconductor structure includes a second bonding layer and a third bonding layer, the second bonding layer is located between the memory array and the first bonding layer, the third bonding layer is located between the plurality of second connection structures and the third semiconductor structure, and the second bonding layer is bonded to the first bonding layer; and
the third semiconductor structure further comprises a fourth bonding layer between the peripheral circuit and the third bonding layer, and the fourth bonding layer is bonded to the third bonding layer.

12. The semiconductor device according to claim 11, wherein:
a first end of the first connection structure is connected to the bit line, a second end of the first connection structure is connected to the second bonding layer, and the first end of the first connection structure and a second end of the first connection structure are opposite to each other along the extension direction of the first connection structures; and
a first end of the second connection structure is connected to the bit line, a second end of the second connection structure is connected to the third bonding layer, and the first end of the second connection structure and the second end of the second connection structure are opposite to each other along an extending direction of the second connection structure.

13. The semiconductor device according to claim 12, wherein:
a cross-sectional size of the first end of the first connection structure is less than or equal to a cross-sectional size of the second end of the first connection structure; and
a cross-sectional size of the first end of the second connection structure is less than or equal to a cross-sectional size of the second end of the second connection structure.

14. The semiconductor device according to claim 1, wherein the semiconductor device comprises a three-dimensional NAND memory.

15. A semiconductor device, comprising:
a first semiconductor structure and a second semiconductor structure;
wherein the first semiconductor structure is bonded with a first side of the second semiconductor structure;
wherein the first semiconductor structure includes an analog-to-digital conversion circuit; and
wherein the second semiconductor structure comprises a plurality of sub-memory planes, a plurality of bit lines and a plurality of first connection structures, the plurality of sub-memory planes are located between the plurality of bit lines and the first side of the second semiconductor structure and arranged at intervals along an extending direction of the bit lines, and at least one of the first connection structures is located between two adjacent sub-memory planes and is respectively connected to the bit line and the analog-to-digital conversion circuit.

16. The semiconductor device according to claim 15, wherein:
the sub-memory plane comprises a plurality of first memory blocks; and
at least one of the first connection structures extends through at least one of the first memory blocks.

17. The semiconductor device according to claim 15, wherein:
the second semiconductor structure further comprises a second memory block located between two adjacent sub-memory planes; and
the first connection structure located between the two adjacent sub-memory planes extends through the second memory block.

18. The semiconductor device according to claim 15, wherein:
the semiconductor device further comprises a third semiconductor structure, the third semiconductor structure is bonded with a second side of the second semiconductor structure, and the second side of the second semiconductor structure and the first side of the second semiconductor structure are opposite to each other along an extension direction of the first connection structures;
the third semiconductor structure includes a peripheral circuit; and
the second semiconductor structure further comprises a plurality of second connection structures located between the plurality of bit lines and the third semiconductor structure, and each of the bit lines is connected to the peripheral circuit through one of the second connection structures.

19. The semiconductor device according to claim 18, wherein:
the first semiconductor structure further comprises a control circuit;
the second semiconductor structure further comprises a source layer located between the plurality of sub-memory planes and the first semiconductor structure; and
the source layer is connected to at least one of the peripheral circuit and the control circuit.

20. A method of operating a semiconductor device, comprising:
performing a first operation on a plurality of sub-memory planes in a second semiconductor structure to obtain analog computing information;
transmitting the analog computing information to an analog-to-digital conversion circuit in a first semiconductor structure through a plurality of bit lines and a plurality of first connection structures in the second semiconductor structure, wherein the first semiconductor structure is bonded with a first side of the second semiconductor structure, and at least one of the first connection structures is located between two adjacent sub-memory planes and respectively connected to the bit line and the analog-to-digital conversion circuit; and
converting the analog computing information into digital information through the analog-to-digital conversion circuit.
